(19) United States
(12) Patent Application Publication
(10) Pub. No.: US 2025/0221191 A1
(43) Pub. Date: Jul. 3, 2025

(54) DISPLAY PANEL, DISPLAY APPARATUS, AND MANUFACTURING METHOD FOR DISPLAY PANEL

(71) Applicants: Hefei Visionox Technology Co., Ltd., Hefei (CN); KunShan Go-Visionox Opto-Electronics Co., Ltd, Kunshan (CN)

(72) Inventors: Zhiwei ZHOU, Hefei (CN); Jinfang ZHANG, Hefei (CN); Lu ZHANG, Hefei (CN)

(73) Assignees: Hefei Visionox Technology Co., Ltd., Hefei (CN); KunShan Go-Visionox Opto-Electronics Co., Ltd, Kunshan (CN)

(21) Appl. No.: 18/746,493

(22) Filed: Jun. 18, 2024

(30) Foreign Application Priority Data
Jan. 2, 2024 (CN) 202410005684.8

(51) Int. Cl. H10K 59/131; H10K 59/12; H10K 59/122; H10K 59/40; H10K 71/20; H10K 71/60

(52) U.S. Cl. CPC H10K 59/131; H10K 59/1201; H10K 59/122; H10K 59/40; H10K 71/233; H10K 71/60

(57) ABSTRACT

A display panel, a display apparatus, and a manufacturing method for a display panel. The display panel includes: a base plate; an electrically conductive layer arranged at a side of the base plate and including a connection portion and a shielding portion; an isolation structure arranged at a side of the electrically conductive layer away from the base plate, in which the isolation structure encloses and forms an isolation opening and a light transmission opening, and at least a part of the shielding portion is exposed in the light transmission opening; a first electrode layer including a first electrode at least partially arranged in the isolation opening, in which the first electrode is electrically connected with the connection portion.

### CROSS REFERENCE TO RELATED APPLICATION

The present application claims priority to Chinese Patent Application No. 202410005684.8 filed on Jan. 2, 2024, and titled “DISPLAY PANEL, DISPLAY APPARATUS, AND MANUFACTURING METHOD FOR DISPLAY PANEL”, which is incorporated herein by reference in its entirety.

### TECHNICAL FIELD

The present application relates to the field of display technology, and particularly to a display panel, a display apparatus, and a manufacturing method for a display panel.

### BACKGROUND

Planar display apparatus based on Organic Light Emitting Diode (OLED) and Light Emitting Diode (LED), etc., are widely used in cell phones, TVs, notebook computers, desktop computers and other consumer electronic products due to their high image quality, power saving, thin body and wide range of applications, and have become the mainstream of the display apparatus. However, the performance of current OLED display products needs to be improved.

### SUMMARY

Embodiments of the present application provide a display panel, a display apparatus, and a manufacturing method for a display panel, aiming to improve the light transmission performance and working stability of the display panel.

Some embodiments of a first aspect of the present application provide a display panel, including: a base plate; an electrically conductive layer arranged at a side of the base plate and including a connection portion and a shielding portion; an isolation structure arranged at a side of the electrically conductive layer away from the base plate, in which the isolation structure encloses and forms an isolation opening and a light transmission opening, and at least a part of the shielding portion is exposed in the light transmission opening; a first electrode layer including a first electrode at least partially arranged in the isolation opening, in which the first electrode is electrically connected with the connection portion.

Some embodiments of a first aspect of the present application further provide a display panel having a display area and a non-display area, the display panel includes: a base plate; an electrically conductive layer arranged at a side of the base plate and including a connection portion and a shielding portion, in which at least a part of the shielding portion is located in the non-display area; an isolation structure located in the display area and arranged at a side of the electrically conductive layer away from the base plate, in which the isolation structure encloses and forms an isolation opening; a first electrode layer including a first electrode at least partially arranged in the isolation opening, in which the first electrode is electrically connected with the connection portion.

Some embodiments of a second aspect of the present application provide a display apparatus including the display panel according to any of the above implementation.

Some embodiments of a third aspect of the present application provide a manufacturing method for a display panel, including:
forming an electrically conductive material layer and an isolation material layer that are stacked on a base plate in sequence;
patterning the electrically conductive material layer and the isolation material layer to form an electrically conductive layer and an isolation structure, in which the electrically conductive layer includes a connection portion and a shielding portion that are connected with each other, the isolation structure is arranged at a side of the electrically conductive layer away from the base plate, the isolation structure encloses and forms an isolation opening and a light transmission opening, and at least a part of the shielding portion is exposed in the light transmission opening; and
preparing a first electrode layer including a first electrode at least partially arranged in the isolation opening, in which the first electrode overlaps and connects the connection portion.

Some embodiments of a third aspect of the present application further provide a manufacturing method for a display panel, including:
forming an electrically conductive material layer on the base plate;
patterning the electrically conductive material layer to form an electrically conductive layer;
forming an isolation material layer on the electrically conductive layer;
patterning the isolation material layer to form a third preliminary structure, wherein the third preliminary structure is provided with an isolation preliminary opening and a light transmission opening, and at least a part of the electrically conductive layer is exposed in the light transmission opening;
patterning an inner wall enclosing and forming the isolation preliminary opening to form an isolation structure, in which the isolation structure is provided with an isolation opening and includes a first isolation portion and a second isolation portion located at a side of the first isolation portion away from the base plate, and the second isolation portion protrudes toward the isolation opening from the first isolation portion;
preparing a first electrode layer including a first electrode at least partially arranged in the isolation opening, in which the first electrode overlaps and connects the isolation structure.

Some embodiments of a third aspect of the present application further provide a manufacturing method for a display panel, including:
forming an electrically conductive material layer on the base plate;
patterning the electrically conductive material layer to form an electrically conductive layer;
forming an isolation material layer on the electrically conductive layer;
patterning the isolation material layer to form a fourth preliminary structure, in which the fourth preliminary structure is provided with an isolation opening, the fourth preliminary structure includes a third preliminary isolation portion and a fourth preliminary isolation portion located at a side of the third preliminary isolation portion away from the base plate, and the fourth preliminary isolation portion protrudes toward the isolation opening from the third preliminary isolation portion;
patterning the fourth preliminary structure to form an isolation structure, in which the isolation structure is provided with a light transmission opening, and at least a part of the electrically conductive layer is exposed in the light transmission opening, the isolation structure includes a first isolation portion and a second isolation portion located at a side of the first isolation portion away from the base plate, and the second isolation portion protrudes toward the isolation opening from the first isolation portion;
preparing a first electrode layer including a first electrode at least partially arranged in the isolation opening, in which the first electrode overlaps and connects the isolation structure.

The display panel according to the embodiments of the present application includes the base plate, the electrically conductive layer, the isolation structure, and the first electrode layer. The electrically conductive layer is arranged at a side of a base plate and includes the connection portion and the shielding portion, the isolation structure is arranged at a side of the electrically conductive layer away from the base plate and encloses and forms the isolation opening, the first electrode layer includes the first electrode at least partially arranged in the isolation opening, the isolation structure may be configured to divide sub-pixels of the display panel, and in the process of manufacturing the display panel, the light-emitting material of the display panel can enter the connection opening through the isolation opening after isolation by the isolation structure. The first electrode is electrically connected with the connection portion such that first electrodes in adjacent isolation openings can be electrically connected with each other through the electrically conductive layer to form a surface electrode, so as to facilitate control of the first electrode in the display panel.

By providing the light transmission opening on the isolation structure, the display panel can have a better light transmission capability. By exposing the shielding portion on the electrically conductive layer in the light transmission opening, the shielding portion can better reduce the crosstalk generated between the signals in the base plate and the signals in a device arranged at a side of the shielding portion away from the base plate through the light transmission opening. For example, the shielding portion can better reduce the crosstalk generated between the signals in the base plate and the touch control signals in the touch control electrode located at a side of the shielding portion away from the base plate through the light transmission opening, so that not only the display panel can have a better light transmission capability, but also the display panel can have a better working stability.

### BRIEF DESCRIPTION OF THE DRAWINGS

In order to more clearly illustrate the technical solutions of the embodiments of the present application, the drawings to be used in the embodiments of the present application will be briefly introduced below. It is obvious that the drawings described below are merely some embodiments of the present application, and for those of ordinary skill in the art, other drawings can be obtained based on these drawings without inventive effort.

FIG. 1 shows a schematic structural diagram of an isolation structure and an electrically conductive layer according to an embodiment of the present application;

FIG. 2 shows a schematic structural diagram of an isolation structure and an electrically conductive layer according to another embodiment of the present application;

FIG. 3 shows a partial sectional view of a display panel according to an embodiment of the present application;

FIG. 4 shows a partial sectional view of a display panel according to another embodiment of the present application;

FIG. 5 shows a partial sectional view of a display panel according to yet another embodiment of the present application;

FIG. 6 shows a schematic structural diagram of a display panel according to an embodiment of the present application;

FIG. 7 shows a partial sectional view of a display panel according to yet another embodiment of the present application;

FIG. 8 shows a schematic flowchart of a manufacturing method for a display panel according to an embodiment of the present application;

FIGS. 9 to 23 show schematic views of a manufacturing process of a manufacturing method for a display panel according to an embodiment of the present application;

FIG. 24 shows a schematic flowchart of a manufacturing method for a display panel according to another embodiment of the present application;

FIGS. 25 to 33 show schematic views of a manufacturing process of a manufacturing method for a display panel according to another embodiment of the present application;

FIG. 34 shows a schematic flowchart of a manufacturing method for a display panel according to yet another embodiment of the present application;

FIGS. 35 to 48 show schematic views of a manufacturing process of a manufacturing method for a display panel according to yet another embodiment of the present application.

### REFERENCE NUMERALS

10, display panel; 10a, pixel definition material layer; 10b, electrically conductive material layer; 10c, isolation material layer; 10d, first material layer; 10e, second material layer; 10f, isolation preliminary opening; 11, first preliminary structure; 12, second preliminary structure; 12a, first primary isolation portion; 12b, second preliminary isolation portion; 13, third preliminary structure; 14, fourth preliminary structure; 14a, third preliminary isolation portion; 14b. fourth preliminary isolation portion; 15, photoresist layer; 15a, first thickness area; 15b, second thickness area; 15c, first hollow area; 15d, second hollow area;
100, base plate;; 110, substrate; 120, first insulating layer; 130, second insulating layer; 140, third insulating layer; 150, driving circuit; 151, transistor; 151a, gate; 151b, source/drain; 152, storage capacitor; 152a, first electrode plate; 152b, second electrode plate;
200, second electrode layer; 210, second electrode;
300, pixel definition portion; 300a, accommodating slot;
400, electrically conductive layer; 400a, connection opening; 410, connection portion; 420, shielding portion;
500, isolation structure; 500a, isolation opening; 500b, light transmission opening; 510, first isolation portion; 520, second isolation portion;
600, light-emitting layer; 610, light-emitting unit;
700, first electrode layer; 710, first electrode;
800, encapsulation layer; 810, first encapsulation layer; 820, second encapsulation layer; 830, third encapsulation layer;
900, touch control component; 910, touch control electrode; 920, touch control signal line;
AA, display area; AA1, first area; AA2, second area;
NA, non-display area;

### DETAILED DESCRIPTION

Features and exemplary embodiments of various aspects of the present application will be described in detail below. In order to make the objectives, technical solutions, and advantages of the present application clearer, the present application will be further described in detail below with reference to the drawings and specific embodiments. It should be understood that the specific embodiments described herein are merely configured to explain the present application, rather than to limit the present application. For those skilled in the art, the present application can be implemented without some of these specific details. The following description of the embodiments is merely to provide a better understanding of the present application by illustrating the examples of the present application.

The embodiments of the present application provide a display panel, a display apparatus, and a manufacturing method for a display panel, and various embodiments of the display panel, the display apparatus, and the manufacturing method for the display panel will be described below in connection with the accompanying drawings.

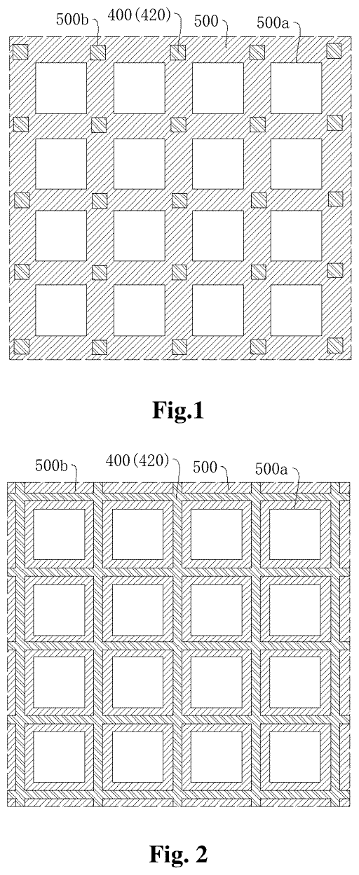

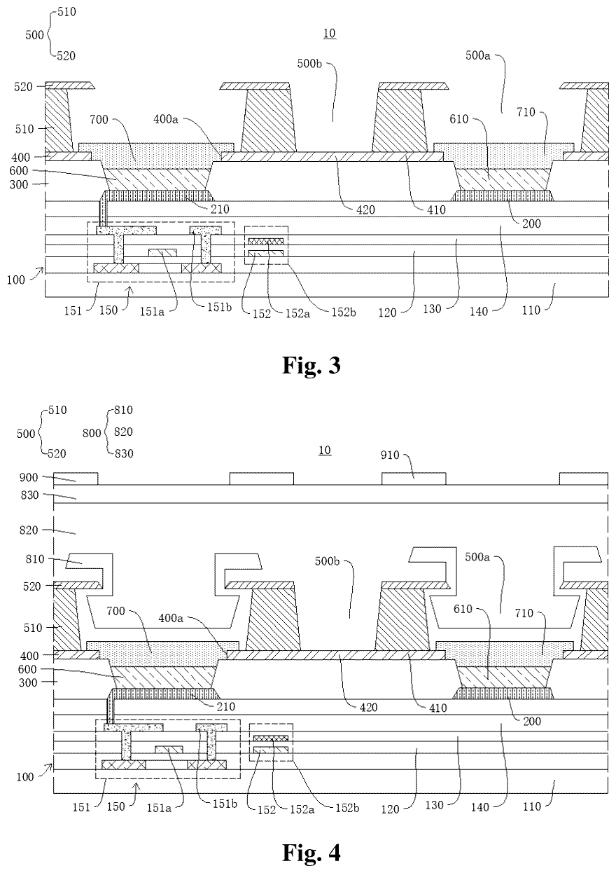

FIG. 1 shows a schematic structural diagram of an isolation structure 500 and an electrically conductive layer 400 according to an embodiment of the present application, FIG. 2 shows a schematic structural diagram of an isolation structure 500 and an electrically conductive layer 400 according to another embodiment of the present application, and FIG. 3 shows a partial sectional view of a display panel 10 according to an embodiment of the present application.

Related technical solutions of the isolation structure are recited in patent applications No. PCT/CN2023/134518, CN 202310759370.2, CN 202310740412.8, CN 202310707209.0, and CN 202311346196.5. The contents of the above applications are incorporated herein by reference, and reference can be made to the above applications, which is not repeated in the present embodiment.

As shown in FIGS. 1 to 3, the embodiments of the first aspect of the present application provide a display panel 10, including: a base plate 100; an electrically conductive layer 400 arranged at a side of the base plate 100 and including a connection portion 410 and a shielding portion 420; an isolation structure 500 arranged at a side of the electrically conductive layer 400 away from the base plate 100, in which the isolation structure 500 encloses and forms an isolation opening 500a and a light transmission opening 500b, and at least a part of the shielding portion 420 is exposed in the light transmission opening 500b; a first electrode layer 700 including a first electrode 710 at least partially arranged in the isolation opening 500a, in which the first electrode 710 is electrically connected with the connection portion 410.

The display panel 10 according to the embodiments of the present application includes the base plate 100, the electrically conductive layer 400, the isolation structure 500, and the first electrode layer 700. The electrically conductive layer 400 is arranged at a side of a base plate 100 and includes the connection portion 410 and the shielding portion 420, the isolation structure 500 is arranged at a side of the electrically conductive layer 400 away from the base plate 100 and encloses and forms the isolation opening 500a, the first electrode layer 700 includes the first electrode 710 at least partially arranged in the isolation opening 500a, the isolation structure 500 may be configured to divide sub-pixels of the display panel 10, and in the process of manufacturing the display panel 10, the light-emitting material of the display panel 10 can enter the connection opening 400a through the isolation opening 500a after isolation by the isolation structure 500. The first electrode 710 is electrically connected with the connection portion 410 such that first electrodes 710 in adjacent isolation openings 500a can be electrically connected with each other through the electrically conductive layer 400 to form a surface electrode, so as to facilitate control of the first electrode 710 in the display panel 10.

By providing the light transmission opening 500b on the isolation structure 500, the display panel 10 can have a better light transmission capability. By exposing the shielding portion 420 on the electrically conductive layer 400 in the light transmission opening 500b, the shielding portion 420 can better reduce the crosstalk generated between the signals in the base plate 100 and the signals in a device arranged at a side of the shielding portion 420 away from the base plate 100 through the light transmission opening 500b. For example, the shielding portion 420 can better reduce the crosstalk generated between the signals in the base plate 100 and the touch control signals in the touch control electrode 910 located at a side of the shielding portion 420 away from the base plate 100 through the light transmission opening 500b so that not only the display panel 10 can have a better light transmission capability, but also the display panel 10 can have a better working stability.

In some embodiments of the present application, the display panel 10 further includes a light-emitting layer 600, which may include a light-emitting unit 610 located at a side of the first electrode 710 facing the base plate 100.

Optionally, the light-emitting unit 610 may include a Hole Inject Layer (HIL), a Hole Transport Layer (HTL), a light-emitting structure, an Electron Inject Layer (EIL), and an Electron Transport Layer (HTL).

Optionally, the display panel 10 further includes a second electrode layer 200, which includes a second electrode 210 located at a side of the light-emitting unit 610 facing the base plate 100.

In these optional embodiments, the first electrode layer 700 and the second electrode layer 200 may be pixel electrode layers of the display panel 10, and one of the first electrode 710 and the second electrode 210 may be used as an anode and the other may be used as a cathode, so as to drive the light-emitting unit 610 to emit light. In the embodiments of the present application, for example, the first electrode 710 is the cathode of the display panel 10, and the second electrode 210 is the anode of the display panel 10.

Optionally, the connection portion 410 is provided with a connection opening 400a, the connection opening 400a may be communicated with the isolation opening 500a, and at least a part of the first electrode 710 may be arranged in the connection opening 400a, so that the first electrode 710 overlaps and connects the connection portion 410 for electrical connection.

Optionally, the connection portion 410 and the shielding portion 420 are in a one-piece structure such that when the first electrode 710 is electrically connected with the connection portion 410, current in a part of the first electrodes 710 may be further transmitted through the shielding portion 420, so as to reduce the resistance between adjacent first electrodes 710 electrically connected with each other through the electrically conductive layer 400.

Optionally, the isolation structure 500 may be arranged at a side of the connection portion 410 away from the base plate 100.

In some embodiments of the present application, the isolation structure 500 and the electrically conductive layer 400 may be in a mesh shape, hollow areas in the mesh-shaped isolation structure 500 may form the isolation openings 500a and the light transmission openings 500b, and hollow areas in the mesh-shaped electrically conductive layer 400 may form the connection openings 400a.

Optionally, the display panel 10 may include a plurality of isolation openings 500a, a plurality of connection openings 400a, a plurality of first electrodes 710, a plurality of light-emitting units 610, and a plurality of second electrodes 210, which may be correspondingly arranged. For example, an orthographic projection of a single isolation opening 500a on the base plate 100 may at least partially overlap an orthographic projection of a single connection opening 400a on the base plate 100, and each of an orthographic projection of the first electrode 710, an orthographic projection of the light-emitting unit 610, and an orthographic projection of the second electrode 210 on the base plate 100 is located within an orthographic projection of the isolation opening 500a on the base plate 100, so that the sub-pixels in the display panel 10 can be divided corresponding to the isolation openings 500a and the connection openings 400a. Herein, the orthographic projection of the isolation opening 500a on the base plate 100 may refer to an orthographic projection of an inner wall enclosing and forming the isolation opening 500a on the base plate 100, and the orthographic projection of the connection opening 400a on the base plate 100 may refer to an orthographic projection of an inner wall enclosing and forming the connection opening 400a on the base plate 100.

In some embodiments of the present application, the shape of the light transmission opening 500b is arranged in various manners. In some optional embodiments, as shown in FIG. 1, the isolation structure 500 encloses and forms a plurality of light transmission openings 500b, and the plurality of light transmission openings 500b may be arranged along a periphery of the isolation opening 500a.

Optionally, a shape of an orthographic projection of the light transmission opening 500b on the base plate 100 may be at least one of a rectangular shape, a square shape, a circular shape, or an irregular polygonal shape.

In these optional embodiments, the isolation structure 500 encloses and forms the plurality of light transmission openings 500b, and the plurality of light transmission openings 500b are spaced apart from each other, so that the light transmission opening 500b can have a relatively small size to facilitate arrangement of the light transmission openings 500b on the isolation structure 500.

In some other optional embodiments, as shown in FIG. 2, an orthographic projection of the light transmission opening 500b on the base plate 100 is in a ring shape, and the light transmission opening 500b is arranged around at least a part of the isolation opening 500a. By arranging the light transmission opening 500b around at least a part of the isolation opening 500a, the space of the periphery of the isolation opening 500a can be more fully used to arrange the light transmission opening 500b, so that the light transmission opening 500b can have a relatively sufficient size to further improve the light transmission performance of the display panel 10.

In some embodiments of the present application, the isolation structure 500 may be used to separate the material for adjacent light-emitting units 610 and the material for adjacent first electrodes 710 in the process of manufacturing the display panel 10.

In some optional embodiments, as shown in FIG. 3, the isolation structure 500 may include a first isolation portion 510 and a second isolation portion 520 located at a side of the first isolation portion 510 away from the base plate 100, and the second isolation portion 520 may protrude toward the isolation opening 500a from the first isolation portion 510.

The second isolation portion 520 of the isolation structure 500 protrudes toward the isolation opening 500a from the first isolation portion 510, so that during vapor deposition of the light-emitting layer 600 and the first electrode layer 700 of the display panel 10, the second isolation portion 520 can block at least a part of the material for manufacturing the light-emitting layer 600 and the first electrode layer 700, so as to separate the material for the light-emitting layer 600 and the first electrode layer 700 that enters different isolation openings 500a, thereby facilitating forming a plurality of light-emitting units 610 and a plurality of first electrodes 710 that are arranged at intervals, and thus no fine mask is required during vapor deposition of the light-emitting layer 600 and the first electrode layer 700 of the display panel 10. For example, no Fine Metal Mask (FMM) is required during vapor deposition of the light-emitting layer 600 and the first electrode layer 700, thereby reducing the cost for manufacturing the display panel 10.

In some optional embodiments, the first electrodes 710 in adjacent connection openings 400a may be electrically connected through the electrically conductive layer 400, that is, the first electrodes 710 of adjacent sub-pixels may be electrically connected through the electrically conductive layer 400. Herein, each of the first electrodes 710 may be further connected with a negative power supply voltage signal line in the display panel 10 through the electrically conductive layer 400, so that the first electrodes 710 may receive a negative power supply voltage signal (ELVSS) through the electrically conductive layer 400, so as to cause the display panel 10 to emit light and display and facilitate control of the first electrode 710 in the display panel 10.

Optionally, an orthographic projection of the first isolation portion 510 on the base plate 100 is located within an orthographic projection of the connection portion 410 on the base plate 100. Optionally, the connection portion 410 may extend into the isolation opening 500a. For example, the connection portion 410 on the electrically conductive layer 400 may protrude towards the connection opening 400a from the first isolation portion 510, so that the connection portion 410 overlaps and connects the first electrode 710, and an overlapping area between the connection portion 410 and the first electrode 710 can be increased, so as to better reduce the overlapping resistance between the connection portion 410 and the first electrode 710, thereby improving the working stability of the display panel 10.

In these optional embodiments, the electrically conductive layer 400 is connected with a negative power supply voltage signal line, which also enables the negative power supply voltage signal line to provide a relatively stable voltage to the electrically conductive layer 400, so that the blocking and shielding effect of the shielding portion 420 on the signals in the base plate 100 and the signals in the device arranged at a side of the shielding portion 420 away from the base plate 100 can be better enhanced, and thus the signals in the base plate 100 are less likely to interfere with the signals in the device arranged at a side of the shielding portion 420 away from the base plate 100.

In some embodiments of the present application, the shielding portion 420 may be configured to block and shield any signal in the base plate 100 that is likely to interfere outward through the light transmission opening 500b. For example, the shielding portion 420 may be configured to reduce the outward crosstalk between the signals in the base plate 100 and light emitting driving signals, light emitting control signals, and the like, through the light transmission opening 500b.

Optionally, the base plate 100 may be arranged in various manners, and for example, the base plate 100 may include a substrate 110 and a driving circuit 150 arranged on the substrate 110. Optionally, the signals in the base plate 100 may refer to signals in the driving circuit 150. Optionally, the base plate 100 may further include a first insulating layer 120, a second insulating layer 130, and a third insulating layer 140 that are stacked. Exemplarily, the driving circuit 150 may include a transistor 151, a storage capacitor 152, and driving signal lines for connecting the individual devices, etc. The transistor 151 may include a semiconductor, a gate 151a, and a source/drain 151b. The storage capacitor 152 may include a first electrode plate 152a and a second electrode plate 152b. As an example, the gate 151a and the first electrode plate 152a may be located at a side of the first insulating layer 120 facing the substrate 110, the second electrode plate 152b may be located between the first insulating layer 120 and the second insulating layer 130, and the source/drain 151b may be located between the second insulating layer 130 and the third insulating layer 140.

FIG. 4 shows a partial sectional view of a display panel according to another embodiment of the present application.

As shown in FIG. 4, in some optional embodiments, the display panel 10 further includes a touch control component 900 located at a side of the isolation structure 500 away from the base plate 100, and the touch control component 900 may include a touch control electrode, which may be configured to participate in the touch control work of the display panel 10. Herein, the shielding portion 420 arranged at the light transmission opening 500b may be configured to reduce the crosstalk between the signals in the base plate 100 and the signals in the touch control electrode 910.

Optionally, the display panel 10 may further include an encapsulation layer 800 for encapsulating the light-emitting unit 610. For example, the encapsulation layer 800 may include a first encapsulation layer 810, a second encapsulation layer 820, and a third encapsulation layer 830. The touch control electrode 910 may be located at a side of the third encapsulation layer 830 away from the base plate 100, the first encapsulation layer 810 may be located in the isolation opening 500a and cover the first electrode 710 and a surface of a part of the isolation structure 500, the second encapsulation layer 820 may be located at a side of the first encapsulation layer 810 away from the base plate 100, and the third encapsulation layer 830 may be located at a side of the second encapsulation layer 820 away from the base plate 100. Herein, a material of the first encapsulation layer 810 may include an inorganic material to better encapsulate the light-emitting unit 610, a material of the second encapsulation layer 820 may include an organic material, so that the second encapsulation layer 820 may have a better flow capability to improve the encapsulation effect of the encapsulation layer 800 on the light-emitting unit 610, and a material of the third encapsulation layer 830 may include an inorganic material.

Optionally, an orthographic projection of the touch control electrode 910 on the base plate 100 is not overlapped with an orthographic projection of the light transmission opening 500b on the base plate 100. For example, the orthographic projection of the touch control electrode 910 on the base plate 100 at least partially overlaps an orthographic projection of the isolation structure 500 on the base plate 100, so that the signals in the base plate 100 are further less likely to interfere with the signals in the touch control electrode 910 through the light transmission opening 500b.

Optionally, the orthographic projection of the touch control electrode 910 on the base plate 100 is located within the orthographic projection of the isolation structure 500 on the base plate 100, so that the signals in the base plate 100 are further less likely to interfere with the signals in the touch control electrode 910 through the light transmission opening 500b.

In some optional embodiments, a material of the electrically conductive layer 400 may include a transparent electrically conductive material. For example, the material of the electrically conductive layer 400 may include at least one of indium zinc oxide (IZO), indium tin oxide (ITO), or zinc oxide, so that the electrically conductive layer 400 may have a better light transmission performance, the shielding portion 420 arranged at the light transmission opening 500b is less likely to affect a light transmittance of the display panel 10, and the photosensitive sensor may better receive or emit light through the shielding portion 420 and the light transmission opening 500b.

In some optional embodiments, an orthographic projection of a surface of the eave 520 at a side facing the light transmission opening 500b on the base plate 100 is located within an orthographic projection of a surface of the first isolation portion 510 at a side away from the base plate 100 on the base plate 100.

Optionally, a cross-section area of the light transmission opening 500b increases in a direction away from the base plate 100.

Optionally, an orthographic projection of the shielding portion 420 on the base plate 100 at least partially overlaps an orthographic projection of the light transmission opening 500b on the base plate 100. For example, the orthographic projection of the shielding portion 420 on the base plate 100 is located within the orthographic projection of the light transmission opening 500b on the base plate 100.

In these optional embodiments, the orthographic projection of the surface of the eave 520 at the side facing the light transmission opening 500b on the base plate 100 is located within the orthographic projection of the surface of the first isolation portion 510 at the side away from the base plate 100 on the base plate 100, that is, a shape of an inner wall enclosing and forming the light transmission opening 500b is set suitably, for example, the cross-section area of the light transmission opening 500b increases in the direction away from the base plate 100, so that the light transmission opening 500b can be manufactured by a dry etching process, and thus when the light transmission opening 500b is manufactured, the process using the dry etching is less likely to cause excessive damage to the shielding portion 420 on the electrically conductive layer 400 located below the light transmission opening 500b than the process using the wet etching to manufacture the light transmission opening 500b, for example, the process using the dry etching is less likely to cause excessive damage to the shielding portion 420 including an indium tin oxide material located below the light transmission opening 500b, and therefore, the shielding portion 420 may have better structural stability, thereby allowing the shielding portion 420 to have better shielding stability to signals.

In some optional embodiments, the display panel 10 may further include a pixel definition portion 300 arranged between the second electrode 210 and the connection portion 410.

Optionally, the pixel definition portion 300 may wrap an edge portion of the second electrode 210 facing the connection portion 410.

In these optional embodiments, the second electrode 210 may be electrically insulated from the connection portion 410 through the pixel definition portion 300 by arranging the pixel definition portion 300 between the second electrode 210 and the connection portion 410, so that short-circuit connection between the second electrode 210 and the first electrode 710 through the electrically conductive layer 400 is less likely to occur, and the light emitting and display reliability of the display panel 10 can be better improved.

In some embodiments of the present application, a relative positional relationship between the electrically conductive layer 400 and the pixel definition portion 300 are arranged in various manners.

In some optional embodiments, as shown in FIGS. 3 and 4, the electrically conductive layer 400 may be arranged at a side of the pixel definition portion 300 away from the base plate 100, that is, the isolation structure 500 may be further arranged at the side of the pixel definition portion 300 away from the base plate 100.

FIG. 5 shows a partial sectional view of a display panel 10 according to yet another embodiment of the present application.

In some other optional embodiments, as shown in FIG. 5, the pixel definition portion 300 is provided with an accommodating slot 300a, and at least a part of the electrically conductive layer 400 and the isolation structure 500 may be located in the accommodating slot 300a, so that the isolation structure 500 will not have an excessively great height in comparison to the base plate 100, so as to better reduce the thickness of the display panel 10.

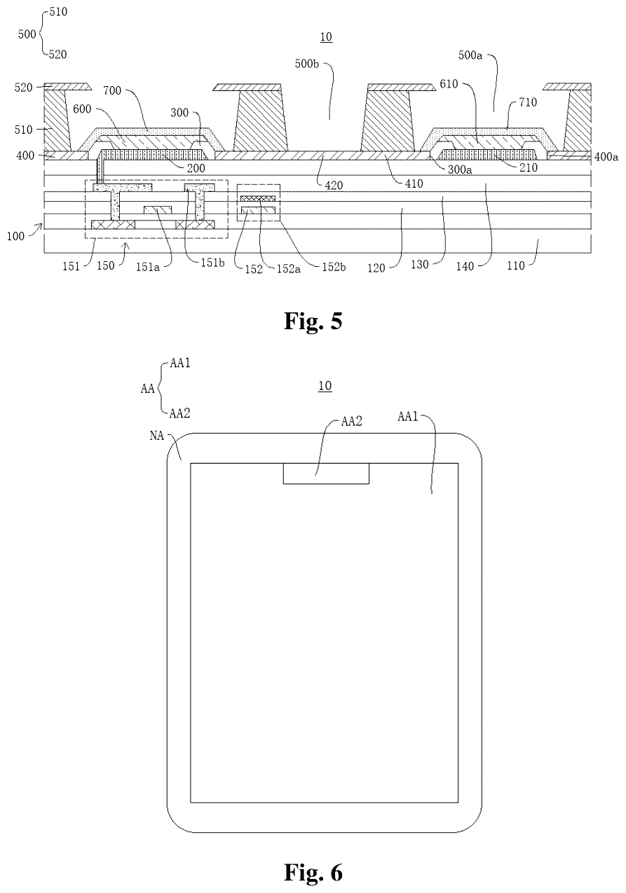

FIG. 6 shows a schematic structural diagram of a display panel 10 according to an embodiment of the present application.

As shown in FIG. 6, in some embodiments of the present application, the display panel 10 has a display area AA and a non-display area NA, the connection opening 400a, the isolation opening 500a, and the light transmission opening 500b may be arranged in the display area AA, and a light-emitting unit 610 corresponding to the connection opening 400a and the isolation opening 500a located in the display area AA may be configured to emit light and display.

Optionally, the display area AA may include a first area AA1 and a second area AA2, a light transmittance of the second area AA2 may be greater than a light transmittance of the first area AA1, in which a photosensitive sensor may be correspondingly arranged near the display panel 10 located in the second area AA2, and the photosensitive sensor may receive or emit light through the display panel 10 in the second area AA2. Optionally, the photosensitive sensor may include at least one of: an ambient light sensor, a camera, a fingerprint sensor, and the like.

Optionally, the connection opening 400a, the isolation opening 500a, and the light-emitting unit 610 may be arranged in both the first area AA1 and the second area AA2, so that the display panel 10 located in both the first area AA1 and the second area AA2 may participate in light emitting and display work.

Optionally, the light transmission opening 500b may be arranged only in the second area AA2, and the light transmission opening 500b located in the second area AA2 may better allow light to pass through, so that the second area AA2 may have a better light transmittance, and thus when the display panel 10 is applied to a display apparatus, a photosensitive sensor in the display apparatus may receive or emit light through the light transmission opening 500b.

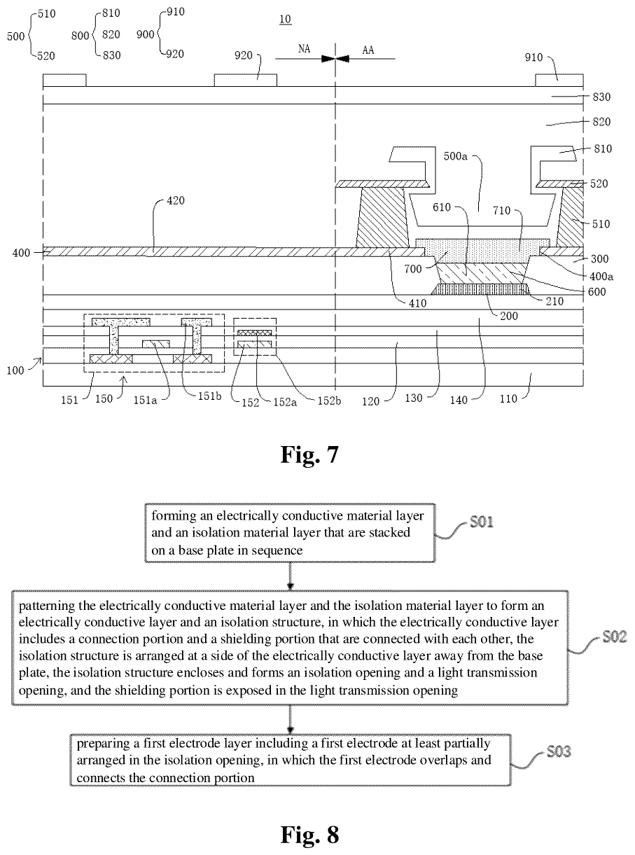

FIG. 7 shows a partial sectional view of a display panel 10 according to yet another embodiment of the present application.

Referring to FIG. 7 in connection with FIGS. 1 to 6, the embodiments of the first aspect of the present application further provide a display panel 10 having a display area AA and a non-display area NA, and the display panel includes: a base plate 100; an electrically conductive layer 400 arranged at a side of the base plate 100 and including a connection portion 410 and a shielding portion 420, in which at least a part of the shielding portion 420 is located in the non-display area NA; an isolation structure 500 arranged at a side of the electrically conductive layer 400 away from the base plate 100, in which the isolation structure 500 encloses and forms an isolation opening 500a; a first electrode layer 700 including a first electrode 710 at least partially arranged in the isolation opening 500a, in which the first electrode 710 is electrically connected with the connection portion 410.

The display panel 10 further provided by the embodiments of the present application includes the base plate 100, the electrically conductive layer 400, the isolation structure 500, and the first electrode layer 700. The electrically conductive layer 400 is arranged at a side of a base plate 100 and includes the connection portion 410 and the shielding portion 420, the isolation structure 500 is arranged at a side of the electrically conductive layer 400 away from the base plate 100 and encloses and forms the isolation opening 500a, the first electrode layer 700 includes the first electrode 710 at least partially arranged in the isolation opening 500a, the isolation structure 500 may be configured to divide sub-pixels of the display panel 10, and in the process of manufacturing the display panel 10, the light-emitting material of the display panel 10 can enter the connection opening 400a through the isolation opening 500a after isolation by the isolation structure 500. The first electrode 710 is electrically connected with the connection portion 410 such that first electrodes 710 in adjacent isolation openings 500a can be electrically connected with each other through the electrically conductive layer 400 to form a surface electrode, so as to facilitate control of the first electrode 710 in the display panel 10.

By arranging at least a part of the shielding portion 420 in the non-display area NA, the shielding portion 420 can better reduce the crosstalk generated between the signals in the base plate 100 in the non-display area NA and the signals in the device arranged at a side of the shielding portion 420 away from the base plate 100, for example, the shielding portion 420 can better reduce the crosstalk generated between the signals in the base plate 100 located in the non-display area NA and the touch control signals in the touch control component 900 located at a side of the shielding portion 420 away from the base plate 100.

Optionally, in the display panel 10 further provided by the embodiments of the first aspect of the present application, the structure of the base plate 100, the isolation structure 500, and the first electrode layer 700 may be the same as or similar to the structure of the base plate 100, the isolation structure 500, and the first electrode layer 700, respectively, in any of the above embodiments. For example, the first electrode 710 of the first electrode layer 700 may be used as the cathode of the display panel 10, and the isolation structure 500 may include the first isolation portion 510 and the second isolation portion 520 to provide better blocking and isolation for the material of the light-emitting layer 600 and the first electrode layer 700.

Optionally, the connection portion 410 and the shielding portion 420 are in a one-piece structure such that when the first electrode 710 is electrically connected with the connection portion 410, current in a part of the first electrodes 710 may be further transmitted through the shielding portion 420, so as to reduce the resistance between adjacent first electrodes 710 electrically connected with each other through the electrically conductive layer 400. Moreover, the electrically conductive layer 400 is connected with the first electrode 710, which also enables the first electrode 710 to provide a relatively stable voltage to the electrically conductive layer 400, so that the blocking and shielding effect of the shielding portion 420 on the signals in the base plate 100 and the signals in the device arranged at a side of the shielding portion 420 away from the base plate 100 can be better enhanced, and thus the signals in the base plate 100 are less likely to interfere with the signals in the device arranged at a side of the shielding portion 420 away from the base plate 100.

Optionally, the isolation structure 500 may be arranged at a side of the connection portion 410 away from the base plate 100, so that the connection portion 410 overlaps and connects the first electrode 710 to facilitate the electrical connection between the connection portion 410 and the first electrode 710.

Optionally, in the display panel 10 further provided by the embodiments of the first aspect of the present application, for the structure of the display panel 10 located in the display area AA, reference may be made to the structure of the display panel 10 in any of the above embodiments. That is, the structure of the display panel 10 provided by yet another embodiment of the present application may be a structure in which a part of the shielding portion 420 is extended to the non-display area NA on the basis of the display panel 10 in any of the above embodiments.

For example, the isolation structure 500 may enclose and form the light transmission opening 500b, and a part of the shielding portion 420 may be exposed in the light transmission opening 500b, so that the shielding portion 420 can better reduce the crosstalk between the signals in the base plate 100 and the signals in the device arranged at a side of the shielding portion 420 away from the base plate 100 through the light transmission opening 500b.

Optionally, a material of the electrically conductive layer 400 may include a transparent electrically conductive material. For example, the material of the electrically conductive layer 400 may include at least one of indium zinc oxide (IZO), indium tin oxide (ITO), or zinc oxide, so that the electrically conductive layer 400 may have a better light transmission performance, the shielding portion 420 arranged at the light transmission opening 500b is less likely to affect a light transmittance of the display panel 10, and the photosensitive sensor may better receive or emit light through the shielding portion 420 and the light transmission opening 500b.

Optionally, the display panel 10 further includes a touch control component 900, the touch control component 900 may include a touch control signal line 920, at least a part of the touch control signal line 920 may be located at a side of the shielding portion 420 in the non-display area NA away from the base plate 100, and the shielding portion 420 can better reduce the crosstalk generated between the signals in the base plate 100 in the non-display area NA and the signals of the touch control signal line 920 arranged at a side of the shielding portion 420 away from the base plate 100.

Optionally, the touch control component 900 may further include a touch control electrode 910, which may be located at a side of the isolation structure 500 away from the base plate 100, in which the shielding portion 420 arranged at the light transmission opening 500b may be configured to reduce the crosstalk between the signals in the base plate 100 and the signals in the touch control electrode 910.

The embodiments of the second aspect of the present application provide a display apparatus including the display panel 10 according to any of the above embodiments. Since the display apparatus according to the embodiments of the second aspect of the present application includes the display panel 10 according to any of the above embodiments of the first aspect, the display apparatus has the beneficial effect of the display panel 10, which will not be repeated herein.

The display apparatus in the embodiments of the present application includes, but is not limited to, a cellular phone, a Personal Digital Assistant (PDA), a tablet computer, an e-book, a television, an entrance guard, a smart fixed-line phone, a console, and other apparatus with display function.

Optionally, the display device may include a photosensitive sensor for sensing light, the light-sensitive sensor may be arranged corresponding to the light transmission opening 500b. For example, at least a part of an orthographic projection of the light-sensitive sensor on the base plate 100 is located within an orthographic projection of an inner wall of the isolation structure 500 enclosing the light transmission opening 500b on the base plate 100, so that light is better sensed by the photosensitive sensor through the light transmission opening 500b.

Optionally, the type of the photosensitive sensor may be set in various manners. For example, the photosensitive sensor may include a distance sensor, a camera, an under-screen fingerprint recognition module, and the like, which can sense light.

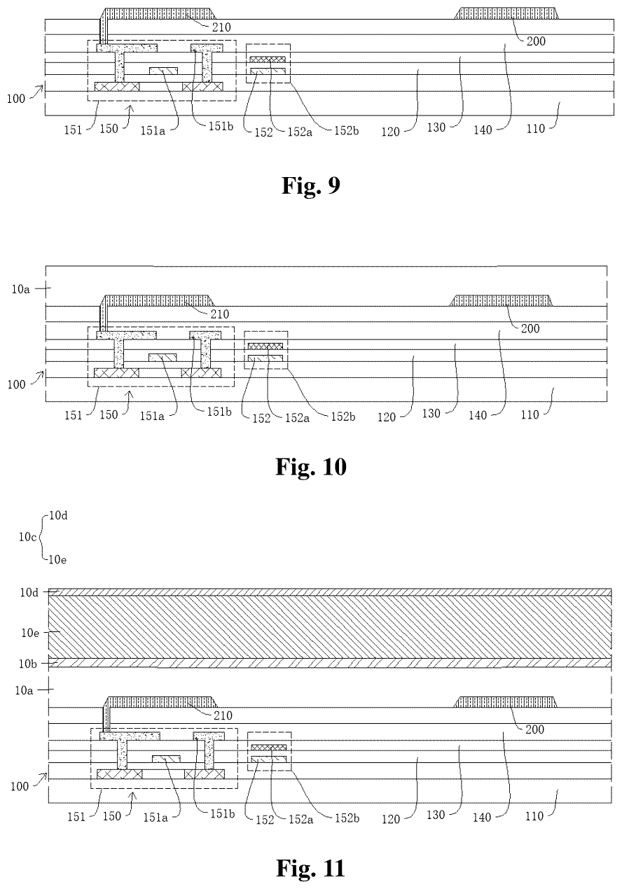

Embodiment of a third aspect of the present application provides a manufacturing method for a display panel 10. As shown in FIGS. 1 to 6, the display panel 10 may be the display panel 10 according to any of the above embodiments of the first aspect. Referring to FIG. 8 in connection with FIGS. 9 to 22, the manufacturing method includes S01 to S03.

Step S01: forming an electrically conductive material layer 10b and an isolation material layer 10c that are stacked on a base plate 100 in sequence as shown in FIGS. 9 to 11.

In some optional embodiments, the manufacturing method, before step S01, may further include:
preparing a second electrode layer 200 on the base plate 100, in which the second electrode layer 200 includes a plurality of second electrodes 210 arranged at intervals as shown in FIG. 9; and
forming a pixel definition material layer 10a on the second electrode layer 200 as shown in FIG. 10.

Step S01 may include: forming the electrically conductive material layer 10b and the isolating material layer 10c that are stacked on the pixel definition material layer 10a in sequence as shown in FIG. 11.

Optionally, the display panel 10 may have a display area AA and a non-display area NA, the base plate 100 includes a power supply voltage signal line, and the manufacturing method, after forming the pixel definition material layer 10a on the second electrode layer 200, may include:
performing an opening treatment on the pixel definition material layer 10a and the base plate 100 located in the non-display area NA to form a via hole, in which at least a part of the power supply voltage signal line is exposed in the via hole; and
forming the conductive material layer 10b and the isolating material layer 10c that are stacked on the pixel definition material layer 10a in sequence, wherein at least a part of the electrically conductive material layer 10b is located in the via hole and is connected with the power supply voltage signal line.

With at least a part of the electrically conductive material layer 10b being located in the via hole and being connected with the power supply voltage signal line, the first electrode 710 of the first electrode layer 700 can be electrically connected with the power supply voltage signal line in the non-display area NA through the electrically conductive layer 400 after the preparation of the electrically conductive layer 400 and the first electrode layer 700 is completed, so that the first electrode 710 can receive a negative power supply voltage signal through the electrically conductive layer 400, thereby causing the display panel 10 to emit light and display.

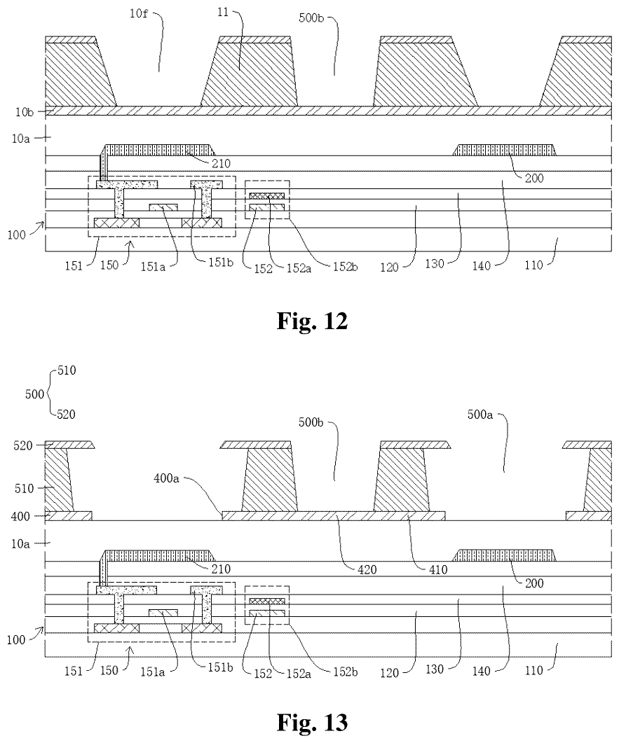

Step S02: patterning the electrically conductive material layer 10b and the isolation material layer 10c to form an electrically conductive layer 400 and an isolation structure 500, in which the electrically conductive layer 400 includes a connection portion 410 and a shielding portion 420 that are connected with each other, the isolation structure 500 is arranged at a side of the electrically conductive layer 400 away from the base plate 100, the isolation structure 500 encloses and forms an isolation opening 500a and a light transmission opening 500b, and at least a part of the shielding portion 420 is exposed in the light transmission opening 500b as shown in FIGS. 12 to 18.

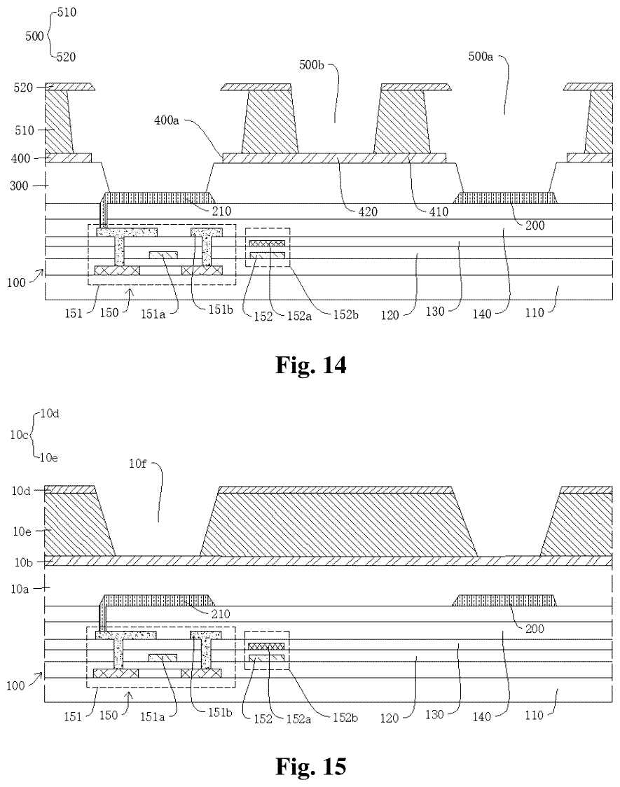

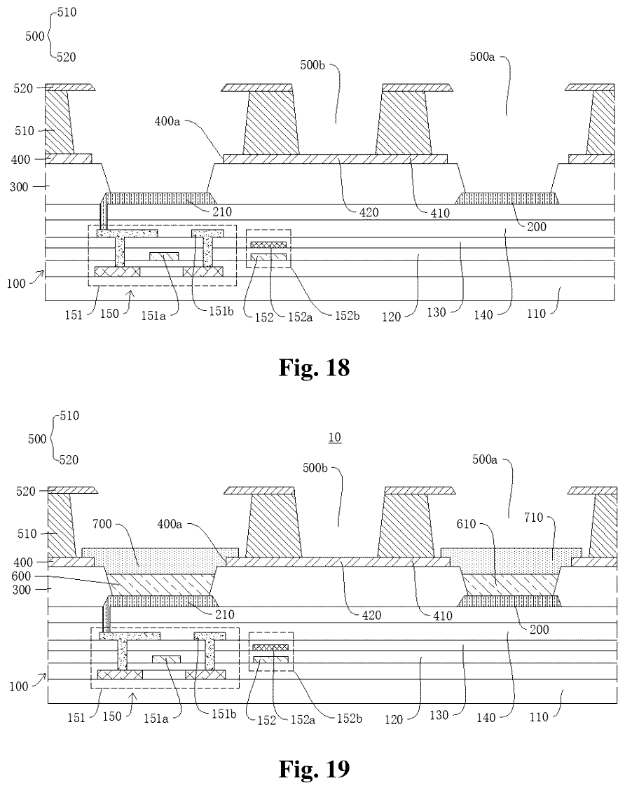

Optionally, the manufacturing method, after step S02, may further include: patterning the pixel definition material layer 10a to form a pixel definition portion 300 arranged between the second electrode 210 and the connection portion 410 as shown in FIGS. 14 and 18.

The pixel definition material layer 10a is patterned after step S02, that is, the pixel definition material layer 10a is patterned after the etching and preparation of the electrically conductive layer 400 and the isolation structure 500 are completed, so that during the etching and preparation of the electrically conductive layer 400 and the isolation structure 500, the pixel definition material layer 10a can better cover the surface of the second electrode 210, and thus the etching material is less likely to cause etching damage to the second electrode 210, thereby better improving the structural stability of the second electrode 210.

Step S03: preparing a first electrode layer 700 including a first electrode 710 at least partially arranged in the isolation opening 500a, in which the first electrode 710 overlaps and connects the connection portion 410 as shown in FIG. 19.

Optionally, one of the first electrode 710 and the second electrode 210 may be used as an anode and the other may be used as a cathode, so as to drive the light-emitting unit 610 to emit light. In the embodiments of the present application, for example, the first electrode 710 is the cathode of the display panel 10, and the second electrode 210 is the anode of the display panel 10.

In the manufacturing method according to the embodiments of the present application, the first electrode 710 is electrically connected with the connection portion 410, so that adjacent first electrodes 710 can be electrically connected with each other through the electrically conductive layer 400 to form a surface electrode, so as to facilitate the control of the first electrode 710 in the display panel 10. By providing the light transmission opening 500b on the isolation structure 500, the display panel 10 can have a better light transmission capability. By exposing the shielding portion 420 on the electrically conductive layer 400 in the light transmission opening 500b, the shielding portion 420 can better reduce the crosstalk generated between the signals in the base plate 100 and the signals in a device arranged at a side of the shielding portion 420 away from the base plate 100 through the light transmission opening 500b. For example, the shielding portion 420 can better reduce the crosstalk generated between the signals in the base plate 100 and the touch control signals in the touch control electrode 910 located at a side of the shielding portion 420 away from the base plate 100 through the light transmission opening 500b so that not only the display panel 10 can have a better light transmission capability, but also the display panel 10 can have a better working stability.

Optionally, a part of the shielding portion 420 may be located in the non-display area NA, so that the shielding portion 420 can further better reduce the crosstalk generated between the signals in the base plate 100 in the non-display area NA and the signals in the device arranged at a side of the shielding portion 420 away from the base plate 100, for example, the shielding portion 420 can better reduce the crosstalk generated between the signals in the base plate 100 located in the non-display area NA and the touch control signals in the touch control component 900 located at a side of the shielding portion 420 away from the base plate 100.

Optionally, step S03 may further include: preparing a light-emitting layer 600, in which the light-emitting layer 600 includes a light-emitting unit 610 located at a side of the first electrode 710 facing the base plate 100.

Optionally, a material of the electrically conductive material layer 10b may include a transparent electrically conductive material. For example, the material of the electrically conductive material layer 10b may include at least one of indium zinc oxide, indium tin oxide, or zinc oxide, so that the electrically conductive layer 400 may have a better light transmission performance, the shielding portion 420 arranged at the light transmission opening 500b is less likely to affect a light transmittance of the display panel 10, and the photosensitive sensor may better receive or emit light through the shielding portion 420 and the light transmission opening 500b.

In some optional embodiments, the isolation structure 500 may include a first isolation portion 510 and a second isolation portion 520 located at a side of the first isolation portion 510 away from the base plate 100, and the second isolation portion 520 may protrude toward the isolation opening 500a from the first isolation portion 510. The second isolation portion 520 of the isolation structure 500 protrudes toward the isolation opening 500a from the first isolation portion 510, so that during vapor deposition of the light-emitting layer 600 and the first electrode layer 700 of the display panel 10, the second isolation portion 520 can block at least a part of the material for manufacturing the light-emitting layer 600 and the first electrode layer 700, so as to facilitate forming a plurality of light-emitting units 610 and a plurality of first electrodes 710 that are arranged at intervals, and thus no fine mask is required during vapor deposition of the light-emitting layer 600 and the first electrode layer 700 of the display panel 10, thereby reducing the cost for manufacturing the display panel 10.

Optionally, a material of the first isolation portion 510 may be different from a material of the second isolation portion 520, so as to form the shape in which the second isolation portion 520 protrudes towards the isolation opening 500a from the first isolation portion 510. Exemplarily, in the direction away from the base plate 100, the isolation material layer 10c may include a first material layer 10d and a second material layer 10e which are stacked in sequence and include different materials, in which when the isolation material layer 10c is patterned, the first material layer 10d may be used to form the first isolation portion 510 and the second material layer 10e may be used to form the second isolation portion 520 in step S02.

In some embodiments of the present application, the electrically conductive layer 400 and the isolation structure 500 are formed in various manners, that is, step S02 is set in various manners.

In some optional embodiments, step S02 may include:
Step S021: patterning the isolation material layer 10c to form a first preliminary structure 11, in which the first preliminary structure 11 is provided with an isolation preliminary opening 10f and a light transmission opening 500b, and at least a part of the electrically conductive material layer 10b is exposed in the isolation preliminary opening 10f and the light transmission opening 500b as shown in FIG. 12.

Optionally, step S021 may include: performing a dry etching treatment on the isolation material layer 10c to form the first preliminary structure 11. By patterning the isolation material layer 10c using a dry etching process to form the light transmission opening 500b, that is, by forming the light transmission opening 500b using a dry etching process, the etching damage effect on the electrically conductive material layer 10b below the isolation material layer 10c when the etching material etches the isolation material layer 10c can be reduced compared to preparing the light transmission opening 500b using a wet etching process. For example, the etching material in the dry etching process is less likely to cause excessive damage to the electrically conductive material layer 10b including the indium tin oxide material located below the light transmission opening 500b when patterning the isolation material layer 10c using a dry etching process, so as to facilitate forming the shielding portion 420 of the electrically conductive layer 400 exposed in the light transmission opening 500b and having better structural stability, thereby causing the shielding portion 420 to have better shielding stability against signals.

Step S022: patterning an inner wall enclosing and forming the isolation preliminary opening 10f and the part of the electrically conductive material layer 10b exposed in the isolation preliminary opening 10f to form the isolation structure 500 and the electrically conductive layer 400 as shown in FIGS. 13 and 14.

Optionally, step S022 may include: performing a wet etching treatment on the inner wall of the first preliminary structure 11 enclosing and forming the isolation preliminary opening 10f and the part of the electrically conductive material layer 10b exposed in the isolation preliminary opening 10f. In this step, the etching material in the wet etching process may be an etching liquid, which may etch a part of the electrically conductive material layer 10b exposed in the isolation preliminary opening 10f. For example, the etching liquid may better etch the electrically conductive material layer 10b including the indium tin oxide material and exposed in the opening, so as to etch and form the connection opening 400a. Moreover, the etching liquid may further etch the inner wall enclosing and forming the isolation preliminary opening 10f to form the first isolation portion 510, the second isolation portion 520 protruding towards the isolation opening 500a from the first isolation portion 510, and the isolation opening 500a enclosed and formed by the first isolation portion 510 and the second isolation portion 520.

When the isolation material layer 10c includes the first material layer 10d and the second material layer 10e that include different materials, the etching liquid may etch a part of the first material layer 10d and the second material layer 10e which enclose and form the isolation preliminary opening 10f. Since the first material layer 10d and the second material layer 10e include different materials, the etching rate of the etching liquid to the first material layer 10d is different from the etching rate of the etching liquid to the second material layer 10e. That is, the materials of the first material layer 10d and the second material layer 10e may be suitably set, for example, the material of the first material layer 10d may include aluminum, and the material of the second material layer 10e may include titanium, so that the etching rate of the etching liquid to the first material layer 10d can be greater than the etching rate of the etching liquid to the second material layer 10e in one etching, so as to facilitate forming the shape in which the second isolation portion 520 protrudes towards the isolation opening 500a from the first isolation portion 510.

In some other optional embodiments, step S02 may include:

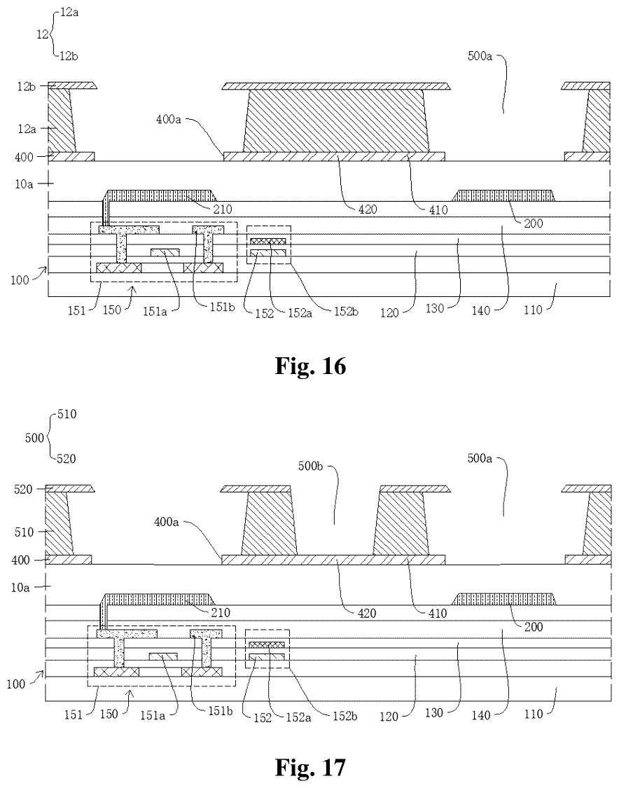

Step S021: patterning the isolation material layer 10c and the electrically conductive material layer 10b to form a second preliminary structure 12 and the electrically conductive layer 400, in which the second preliminary structure 12 is provided with the isolation opening 500a, the second preliminary structure 12 includes a first preliminary isolation portion 12a and a second preliminary isolation portion 12b located at a side of the first preliminary isolation portion 12a away from the base plate 100, and the second preliminary isolation portion 12b protrudes towards the isolation opening 500a from the first preliminary isolation portion 12a as shown in FIGS. 15 and 16.

Optionally, step S021 may include:
performing a dry etching treatment on the isolation material layer 10c to form the isolation preliminary opening 10f as shown in FIG. 15; and
performing a wet etching treatment on an inner wall enclosing and forming the isolation preliminary opening 10f and a part of the electrically conductive material layer 10b exposed in the isolation preliminary opening 10f to form a second preliminary structure 12 and the electrically conductive layer 400 as shown in FIG. 16.

In this optional embodiment, the isolation material layer 10c is patterned using a dry etching process to form the isolation preliminary opening 10f firstly, which can facilitate etching the inner wall enclosing and forming the isolation preliminary opening 10f using a wet etching process subsequently, so as to form the shape in which the second preliminary isolation portion 12b protrudes towards the isolation opening 500a from the first preliminary isolation portion 12a. Moreover, it is further convenient to etch a part of the electrically conductive material layer 10b exposed in the isolation preliminary opening 10f using a wet etching process subsequently. For example, the etching liquid may better etch the electrically conductive material layer 10b including the indium tin oxide material and exposed in the opening.

When the isolation material layer 10c includes the first material layer 10d and the second material layer 10e that include different materials, the first material layer 10d may be used to participate in forming the first primary isolation portion 12a, and the second material layer 10e may be used to participate in forming the second primary isolation portion 12b. When the second preliminary structure 12 is etched using a wet etching process, for example, when a part of the first material layer 10d and the second material layer 10e which enclose and form the isolation preliminary opening 10f is etched using the etching liquid, the specific etching principle of the wet etching process can be similar to the etching principle of the wet etching process in any of the above embodiments. That is, the etching liquid has different etching rates for different materials, and the shape in which the second primary spacer 12b protrudes towards the isolation opening 500a from the first primary isolation portion 12a can be prepared. For ease of description, the wet etching process mentioned in the following embodiments may further obtain a specific shape using the same etching principle, which is not repeated in this application.

Step S022: patterning the second preliminary structure 12 to form the isolation structure 500, in which the isolation structure 500 includes a first isolation portion 510 and a second isolation portion 520 located at a side of the first isolation portion 510 away from the base plate 100, and the second isolation portion 520 protrudes toward the isolation opening 500a from the first isolation portion 510 as shown in FIGS. 17 and 18;

Optionally, step S022 may include: performing a dry etching treatment on the second preliminary structure 12 to form the isolation structure 500. By patterning the second preliminary structure 12 using a dry etching process to form the light transmission opening 500b, that is, by forming the light transmission opening 500b using a dry etching process, the etching damage effect on the electrically conductive layer 400 below the second preliminary structure 12 when the etching material etches the second preliminary structure 12 can be reduced compared to preparing the light transmission opening 500b using a wet etching process. For example, the etching material in the dry etching process is less likely to cause excessive damage to the electrically conductive layer 400 including the indium tin oxide material located below the light transmission opening 500b when patterning the second preliminary structure 12 using a dry etching process, so as to facilitate forming the shielding portion 420 exposed in the light transmission opening 500b and having better structural stability, thereby causing the shielding portion 420 to have better shielding stability against signals.

In some optional embodiments of the present application, the surface at locations where etching is not required may be coated with a photoresist material for protection when a wet etch or dry etch process is used. Optionally, the coating of the photoresist may be performed using a common mask. For example, the coating of the photoresist may be performed before step S021, and then the coating of the photoresist may be performed once after the removal of the original photoresist material before step S022. Optionally, the coating of the photoresist may be performed using similar devices such as a halftone mask (HTM) to form a photoresist with varying thickness.

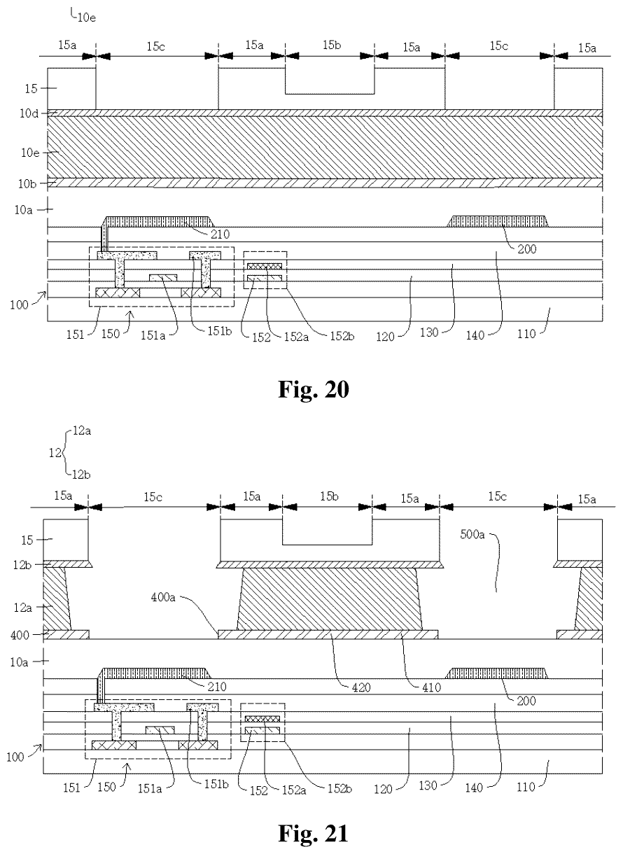

Optionally, the manufacturing method, before step S021, may include: forming a photoresist layer 15 on the isolation material layer 10c, in which the photoresist layer 15 includes a first thickness area 15a, a second thickness area 15b, and a first hollow area 15c, a part of the isolation material layer 10c is exposed in the first hollow area 15c, and a thickness of the photoresist layer 15 located in the first thickness area 15a is greater than a thickness of the photoresist layer 15 located in the second thickness area 15b as shown in FIG. 20.

Optionally, the forming a photoresist layer 15 on the isolation material layer 10c may include: forming the photoresist layer 15 on the isolation material layer 10c using a halftone mask.

Step S021 may further include: patterning the isolation material layer 10c and the electrically conductive material layer 10b corresponding to the first hollow area 15c to form the second preliminary structure 12 and the electrically conductive layer 400 as shown in FIG. 21;

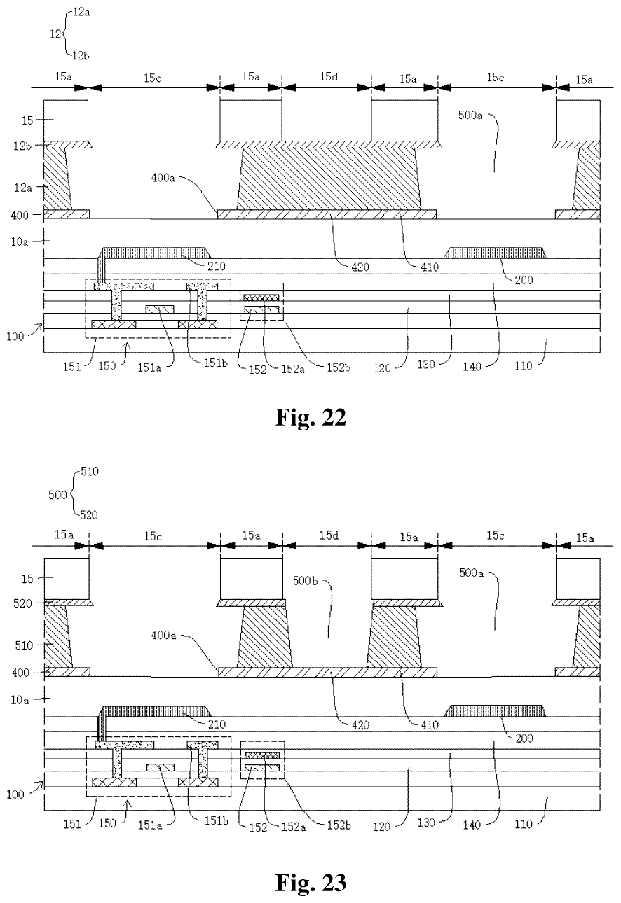

The manufacturing method, after step S021, may further include: removing the photoresist layer 15 in the second thickness area 15b using an ashing process to form a second hollow area 15d as shown in FIG. 22.

Step S022 may further include: patterning the second preliminary structure 12 corresponding to the second hollow area 15d to form the isolation structure 500 as shown in FIG. 23.

In this optional embodiment, the photoresist layer 15 is formed using the halftone mask before patterning the isolation material layer 10c and the electrically conductive layer 400, so that the photoresist layer 15 can have the first thickness area 15a, the second thickness area 15b, and the first hollow area 15c that have different thicknesses. In step S021, the etching material may etch the material exposed in the first hollow area 15c. For example, the isolation material layer 10c exposed in the first hollow area 15c may be etched using a dry etching process firstly so as to obtain the isolation preliminary opening 10f, and then the inner wall enclosing and forming the isolation preliminary opening 10f and a part of the electrically conductive material layer 10b exposed in the first hollow area 15c may be etched using a wet etching method so as to obtain the isolation opening 500a and the connection opening 400a. After step S021, the photoresist layer 15 in the second thickness area 15b is removed by using an ashing process to form the second hollow area 15d, so that a part of the second preliminary structure 12 can be exposed in the second hollow area 15d, so as to facilitate the process of patterning the part of the second preliminary structure 12 exposed in the second hollow area 15d to form the light transmission opening 500b in step S022. In the above steps, the times of coating the photoresist material can be reduced when the coating of the photoresist material is performed using the halftone mask compared to the common mask, and the manufacturing efficiency of the display panel 10 can be improved.

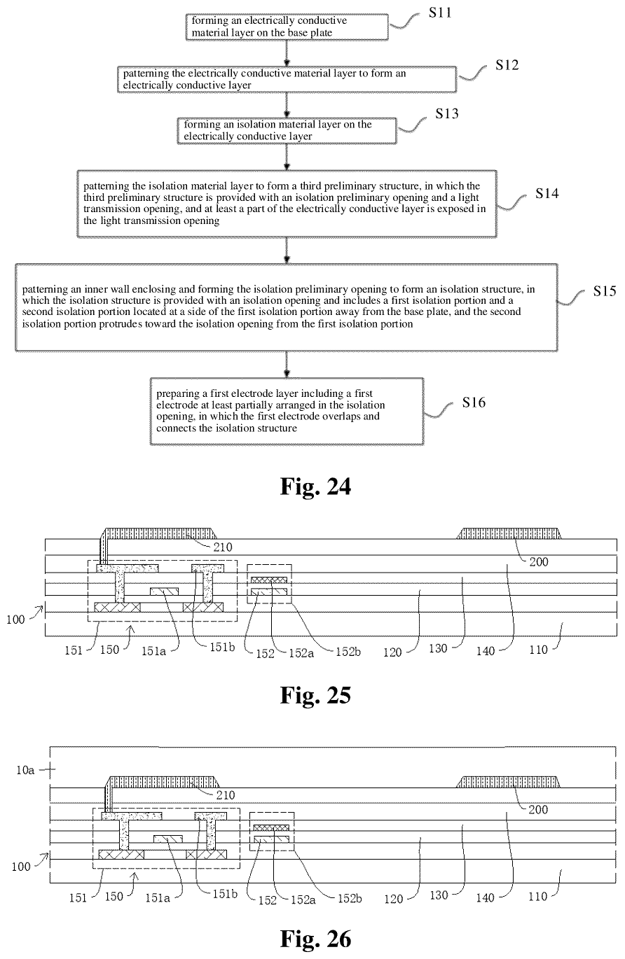

The embodiments of the third aspect of the present application further provide a manufacturing method for a display panel 10. Referring to FIG. 24 in connection with FIGS. 25 to 33, the manufacturing method includes S11 to S16.

Step S11: forming an electrically conductive material layer 10b on the base plate 100 as shown in FIGS. 25 to 27.

Optionally, the manufacturing method, before step S11, may further include:
preparing a second electrode layer 200 on the base plate 100, in which the second electrode layer 200 includes a plurality of second electrodes 210 arranged at intervals as shown in FIG. 25; and
forming a pixel definition material layer 10a on the second electrode layer 200 as shown in FIG. 26.

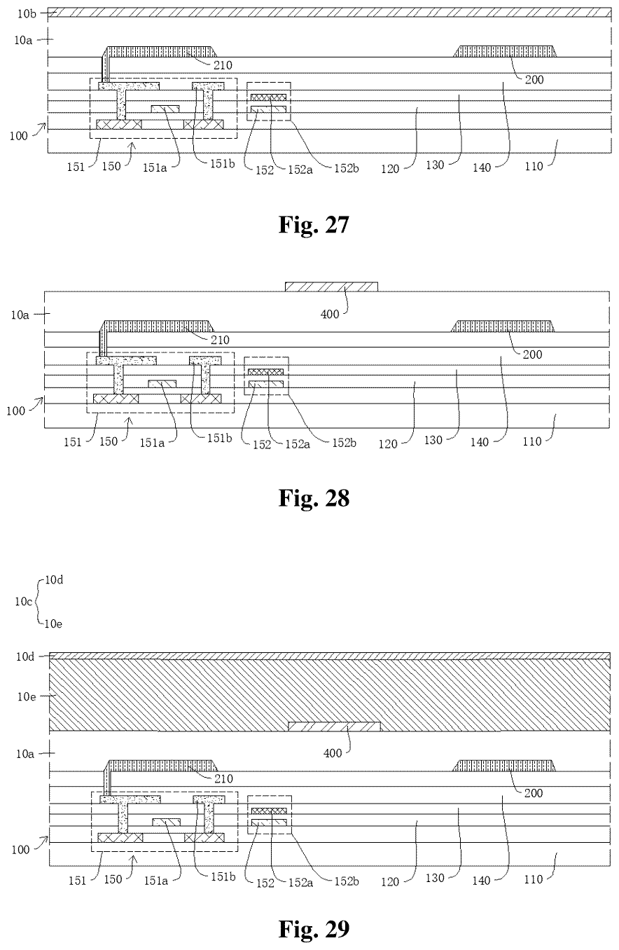

Step S11 may include: forming the electrically conductive material layer 10b on the pixel definition material layer 10a as shown in FIG. 27.

Step S12: patterning the electrically conductive material layer 10b to form an electrically conductive layer 400 as shown in FIG. 28.

Optionally, a material of the electrically conductive material layer 10b may include a transparent electrically conductive material. For example, the material of the electrically conductive material layer 10b may include at least one of indium zinc oxide, indium tin oxide, or zinc oxide. That is, the material of the formed electrically conductive layer 400 may include indium tin oxide, so that the electrically conductive layer 400 may have a better light transmission performance, and thus the photosensitive sensor receives or emits light through the electrically conductive layer 400.

Step S13: forming an isolation material layer 10c on the electrically conductive layer 400 as shown in FIG. 29.

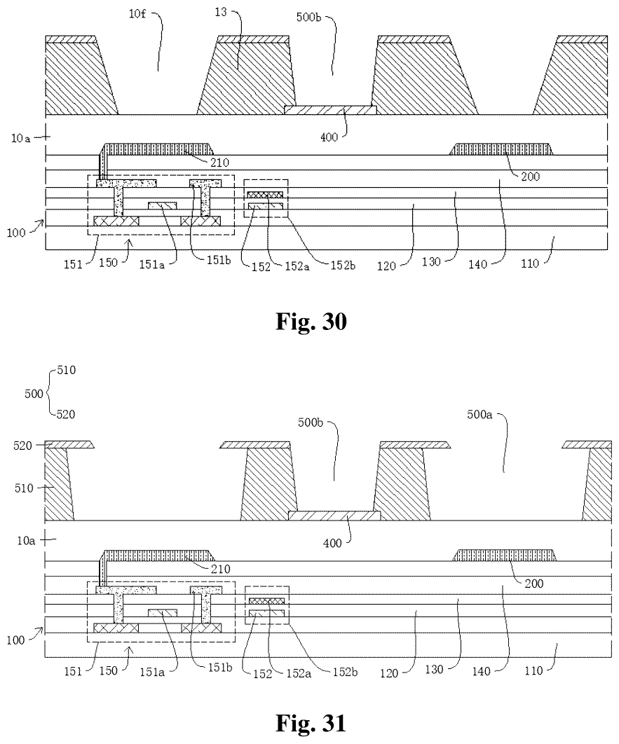

Step S14: patterning the isolation material layer 10c to form a third preliminary structure 13, in which the third preliminary structure 13 is provided with an isolation preliminary opening 10f and a light transmission opening 500b, and at least a part of the electrically conductive layer 400 is exposed in the light transmission opening 500b as shown in FIG. 30.

Optionally, step S14 may include: performing a dry etching treatment on the isolation material layer 10c to form the third preliminary structure 13. By patterning the isolation material layer 10c using a dry etching process to form the light transmission opening 500b, that is, by forming the light transmission opening 500b using a dry etching process, the etching damage effect on the electrically conductive layer 400 below the isolation material layer 10c when the etching material etches the isolation material layer 10c can be reduced compared to preparing the light transmission opening 500b using a wet etching process. For example, the etching material in the dry etching process is less likely to cause excessive damage to the electrically conductive layer 400 including the indium tin oxide material located below the light transmission opening 500b when patterning the isolation material layer 10c using a dry etching process, so as to facilitate forming the electrically conductive layer 400 exposed in the light transmission opening 500b and having better structural stability, thereby causing the electrically conductive layer 400 to have better shielding stability against signals.

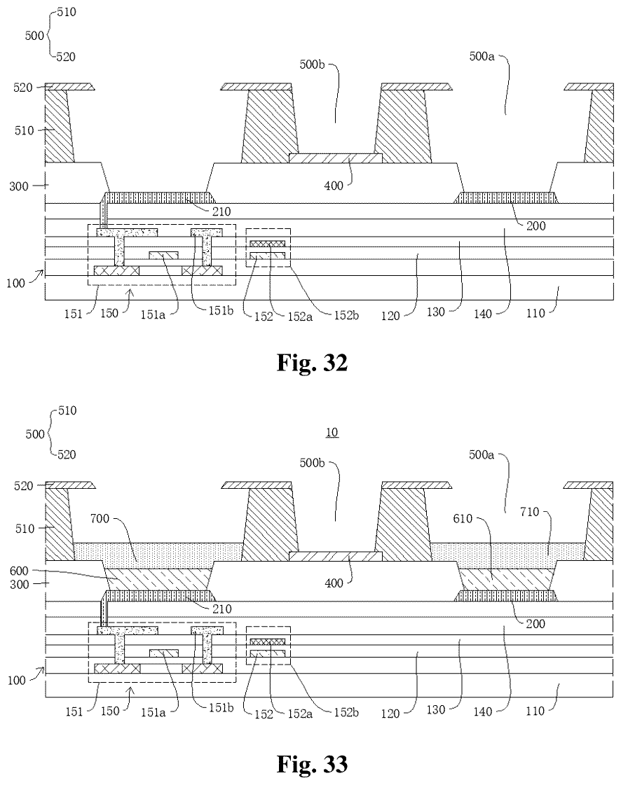

Step S15: patterning an inner wall enclosing and forming the isolation preliminary opening 10f to form an isolation structure 500, in which the isolation structure 500 is provided with an isolation opening 500a and includes a first isolation portion 510 and a second isolation portion 520 located at a side of the first isolation portion 510 away from the base plate 100, and the second isolation portion 520 protrudes toward the isolation opening 500a from the first isolation portion 510 as shown in FIGS. 31 and 32.

The second isolation portion 520 of the isolation structure 500 protrudes toward the isolation opening 500a from the first isolation portion 510, so that during vapor deposition of the light-emitting layer 600 and the first electrode layer 700 of the display panel 10, the second isolation portion 520 can block at least a part of the material for manufacturing the light-emitting layer 600 and the first electrode layer 700, so as to facilitate forming a plurality of light-emitting units 610 and a plurality of first electrodes 710 that are arranged at intervals, and thus no fine mask is required during vapor deposition of the light-emitting layer 600 and the first electrode layer 700 of the display panel 10, thereby reducing the cost for manufacturing the display panel 10.

Optionally, a material of the first isolation portion 510 may be different from a material of the second isolation portion 520, so as to form the shape in which the second isolation portion 520 protrudes towards the isolation opening 500a from the first isolation portion 510. Exemplarily, in the direction away from the base plate 100, the isolation material layer 10c may include a first material layer 10d and a second material layer 10e which are stacked in sequence and include different materials, in which when the isolation material layer 10c is patterned, the first material layer 10d may be used to form the first isolation portion 510 and the second material layer 10e may be used to form the second isolation portion 520 in step S15.

Optionally, step S15 may include: performing a wet etching treatment on the inner wall of the third preliminary structure 13 enclosing and forming the isolation preliminary opening 10f. In this step, the etching material in the wet etching process may be an etching liquid, which may etch a part of the first material layer 10d and the second material layer 10e which enclose and form the isolation preliminary opening 10f. Since the first material layer 10d and the second material layer 10e include different materials, the etching rate of the etching liquid to the first material layer 10d is different from the etching rate of the etching liquid to the second material layer 10e. That is, the materials of the first material layer 10d and the second material layer 10e may be suitably set, for example, the material of the first material layer 10d may include aluminum, and the material of the second material layer 10e may include titanium, so that the etching rate of the etching liquid to the first material layer 10d can be greater than the etching rate of the etching liquid to the second material layer 10e in one etching, so as to facilitate forming the shape in which the second isolation portion 520 protrudes towards the isolation opening 500a from the first isolation portion 510.

Optionally, the manufacturing method, after step S15, may further include: patterning the pixel definition material layer 10a to form a pixel definition portion 300 arranged between the second electrode 210 and the isolation structure 500 as shown in FIG. 32.

The second electrode 210 may be electrically insulated from the isolation structure 500 through the pixel definition portion 300, so that short-circuit connection is less likely to be generated between the second electrode 210 and the first electrode 710 through the isolation structure 500. The pixel definition material layer 10a is patterned after step S15, that is, the pixel definition material layer 10a is patterned after the etching and preparation of the electrically conductive layer 400 and the isolation structure 500 are completed, so that during the etching and preparation of the electrically conductive layer 400 and the isolation structure 500, the pixel definition material layer 10a can better cover the surface of the second electrode 210, and thus the etching material is less likely to cause etching damage to the second electrode 210, thereby better improving the structural stability of the second electrode 210.

Step S16: preparing a first electrode layer 700 including a first electrode 710 at least partially arranged in the isolation opening 500a, in which the first electrode 710 overlaps and connects the isolation structure 500 as shown in FIG. 33.

Optionally, one of the first electrode 710 and the second electrode 210 may be used as an anode and the other may be used as a cathode, so as to drive the light-emitting unit 610 to emit light. In the embodiments of the present application, for example, the first electrode 710 is the cathode of the display panel 10, and the second electrode 210 is the anode of the display panel 10.

Optionally, step S16 may further include: preparing a light-emitting layer 600, in which the light-emitting layer 600 includes a light-emitting unit 610 located at a side of the first electrode 710 facing the base plate 100.

In the manufacturing method according to the embodiments of the present application, the first electrode 710 overlaps and connects the isolation structure 500, so that adjacent first electrodes 710 can be electrically connected with each other through the isolation structure 500 to form a surface electrode, so as to facilitate the control of the first electrode 710 in the display panel 10. By providing the light transmission opening 500b on the isolation structure 500, the display panel 10 can have a better light transmission capability. By exposing at least a part of the electrically conductive layer 400 in the light transmission opening 500b, the electrically conductive layer 400 can better reduce the crosstalk generated between the signals in the base plate 100 and the signals in a device arranged at a side of the electrically conductive layer 400 away from the base plate 100 through the light transmission opening 500b. For example, the electrically conductive layer 400 can better reduce the crosstalk generated between the signals in the base plate 100 and the touch control signals in the touch control electrode 910 located at a side of the shielding portion 420 away from the base plate 100 through the light transmission opening 500b so that not only the display panel 10 can have a better light transmission capability, but also the display panel 10 can have a better working stability.

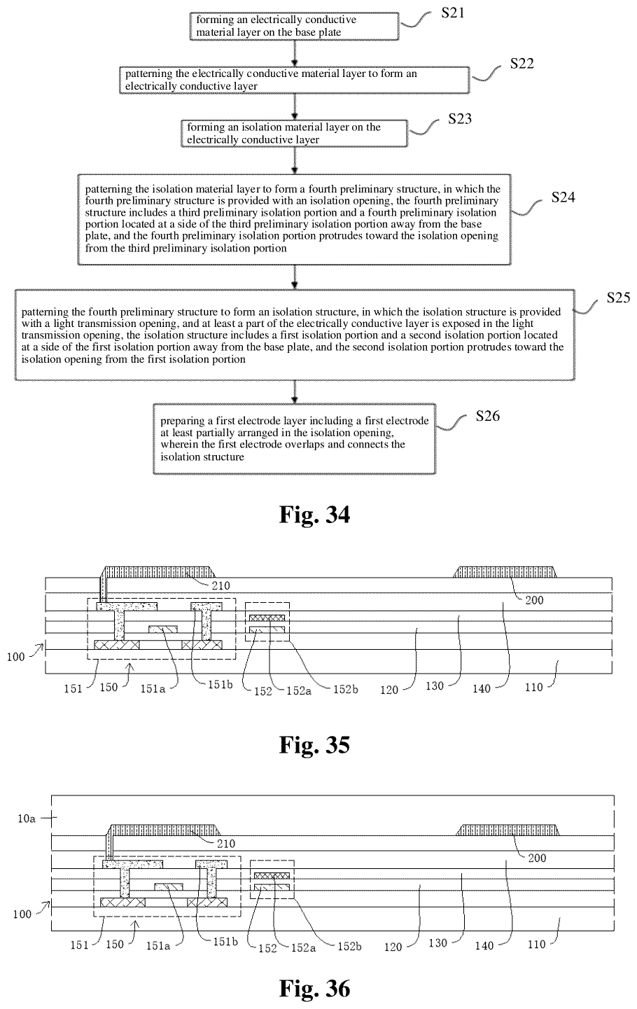

The embodiments of the third aspect of the present application further provide a manufacturing method for a display panel 10. Referring to FIG. 34 in connection with FIGS. 35 to 48, the manufacturing method includes S21 to S26.

Step S21: forming an electrically conductive material layer 10b on the base plate 100 as shown in FIGS. 35 to 37.

Optionally, the manufacturing method, before step S21, may further include:
preparing a second electrode layer 200 on the base plate 100, in which the second electrode layer 200 includes a plurality of second electrodes 210 arranged at intervals as shown in FIG. 35; and
forming a pixel definition material layer 10a on the second electrode layer 200 as shown in FIG. 36.

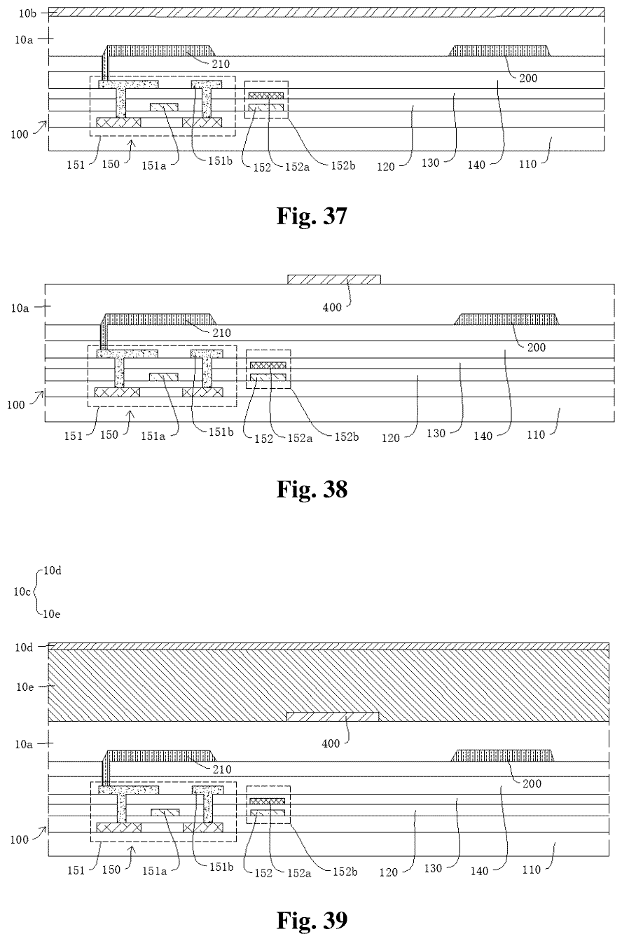

Step S21 may include: forming the electrically conductive material layer 10b on the pixel definition material layer 10a as shown in FIG. 37.

Step S22: patterning the electrically conductive material layer 10b to form an electrically conductive layer 400 as shown in FIG. 38.

Optionally, a material of the electrically conductive material layer 10b may include a transparent electrically conductive material. For example, the material of the electrically conductive material layer 10b may include at least one of indium zinc oxide, indium tin oxide, or zinc oxide. That is, the material of the formed electrically conductive layer 400 may include indium tin oxide, so that the electrically conductive layer 400 may have a better light transmission performance, and thus the photosensitive sensor receives or emits light through the electrically conductive layer 400.

Step S23: forming an isolation material layer 10c on the electrically conductive layer 400 as shown in FIG. 39.

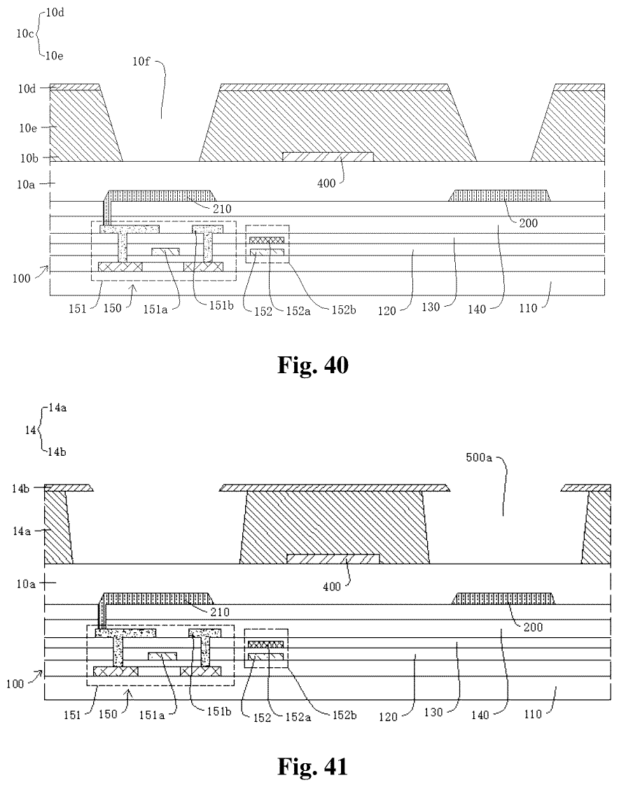

Step S24: patterning the isolation material layer 10c to form a fourth preliminary structure 14, in which the fourth preliminary structure 14 is provided with an isolation opening 500a, the fourth preliminary structure 14 includes a third preliminary isolation portion 14a and a fourth preliminary isolation portion 14b located at a side of the third preliminary isolation portion 14a away from the base plate 100, and the fourth preliminary isolation portion 14b protrudes toward the isolation opening 500a from the third preliminary isolation portion 14a as shown in FIGS. 40 and 41.

Optionally, step S24 may include:
performing a dry etching treatment on the isolation material layer 10c to form the isolation preliminary opening 10f as shown in FIG. 40; and
performing a wet etching treatment on an inner wall enclosing and forming the isolation preliminary opening 10f to form the fourth preliminary structure 14 as shown in FIG. 41.

In this optional embodiment, the isolation material layer 10c is patterned using a dry etching process to form the isolation preliminary opening 10f firstly, which can facilitate etching the inner wall enclosing and forming the isolation preliminary opening 10f using a wet etching process subsequently, so as to form the shape in which the fourth preliminary isolation portion 14b protrudes towards the isolation opening 500a from the third preliminary isolation portion 14a.

The isolation material layer 10c may include the first material layer 10d and the second material layer 10e that include different materials, the first material layer 10d may be used to participate in forming the third preliminary isolation portion 14a, the second material layer 10e may be used to participate in forming the fourth preliminary isolation portion 14b. When the fourth preliminary structure 14 is etched using a wet etching process, for example, when a part of the first material layer 10d and the second material layer 10e which enclose and form the isolation preliminary opening 10f is etched using a etching liquid, the etching rate of the etching liquid to the first material layer 10d is different from the etching rate of the etching liquid to the second material layer 10e since the first material layer 10d and the second material layer 10e include different materials. That is, the materials of the first material layer 10d and the second material layer 10e may be suitably set, for example, the material of the first material layer 10d may include aluminum, and the material of the second material layer 10e may include titanium, so that the etching rate of the etching liquid to the first material layer 10d can be greater than the etching rate of the etching liquid to the second material layer 10e in one etching, so as to facilitate forming the shape in which fourth preliminary isolation portion 14b protrudes towards the isolation opening 500a from the third preliminary isolation portion 14a.

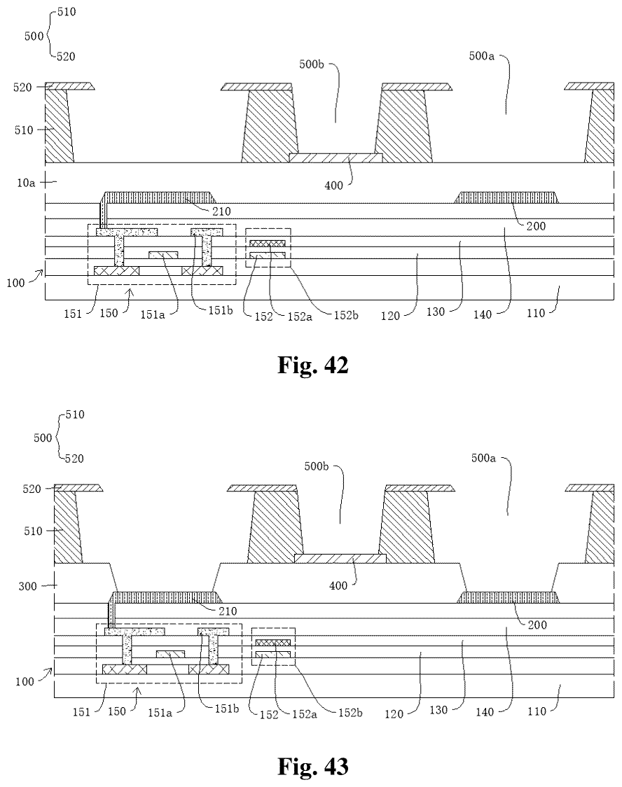

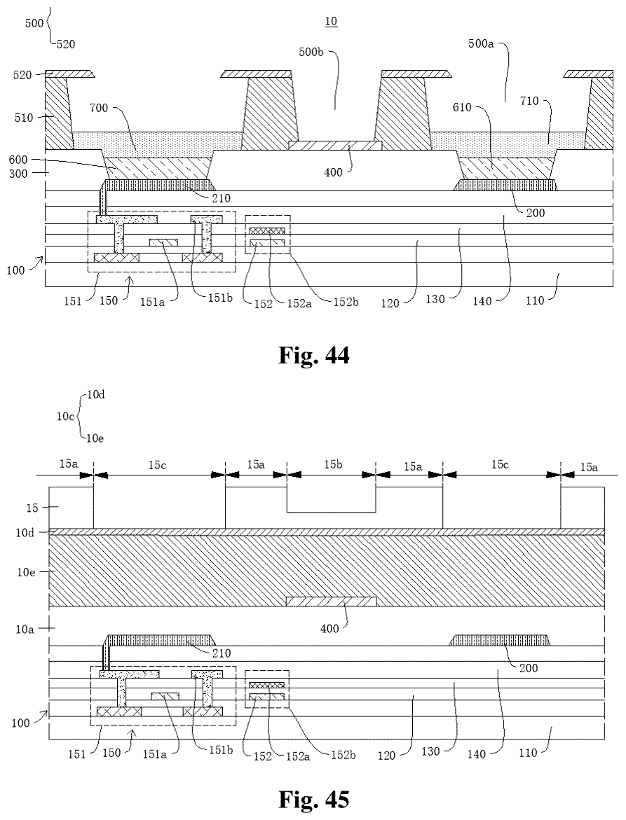

Step S25: patterning the fourth preliminary structure 14 to form an isolation structure 500, in which the isolation structure 500 is provided with a light transmission opening 500b, and at least a part of the electrically conductive layer 400 is exposed in the light transmission opening 500b, the isolation structure 500 includes a first isolation portion 510 and a second isolation portion 520 located at a side of the first isolation portion 510 away from the base plate 100, and the second isolation portion 520 protrudes toward the isolation opening 500a from the first isolation portion 510 as shown in FIGS. 42 and 43.

Optionally, step S25 may include: performing a dry etching treatment on the fourth preliminary structure 14 to form the isolation structure 500. By patterning the fourth preliminary structure 14 using a dry etching process to form the light transmission opening 500b, that is, by forming the light transmission opening 500b using a dry etching process, the etching damage effect on the electrically conductive layer 400 below the fourth preliminary structure 14 when the etching material etches the fourth preliminary structure 14 can be reduced compared to preparing the light transmission opening 500b using a wet etching process. For example, the etching material in the dry etching process is less likely to cause excessive damage to the electrically conductive layer 400 including the indium tin oxide material located below the light transmission opening 500b when patterning the fourth preliminary structure 14 using a dry etching process, so as to facilitate forming the electrically conductive layer 400 exposed in the light transmission opening 500b and having better structural stability, thereby causing the electrically conductive layer 400 to have better shielding stability against signals.

Moreover, the second isolation portion 520 of the isolation structure 500 protrudes toward the isolation opening 500a from the first isolation portion 510, so that during vapor deposition of the light-emitting layer 600 and the first electrode layer 700 of the display panel 10, the second isolation portion 520 can block at least a part of the material for manufacturing the light-emitting layer 600 and the first electrode layer 700, so as to facilitate forming a plurality of light-emitting units 610 and a plurality of first electrodes 710 that are arranged at intervals, and thus no fine mask is required during vapor deposition of the light-emitting layer 600 and the first electrode layer 700 of the display panel 10, thereby reducing the cost for manufacturing the display panel 10.

Optionally, the manufacturing method, after step S25, may further include: patterning the pixel definition material layer 10a to form a pixel definition portion 300 arranged between the second electrode 210 and the isolation structure 500 as shown in FIG. 43.

The second electrode 210 may be electrically insulated from the isolation structure 500 through the pixel definition portion 300, so that short-circuit connection is less likely to be generated between the second electrode 210 and the first electrode 710 through the isolation structure 500. The pixel definition material layer 10a is patterned after step S25, that is, the pixel definition material layer 10a is patterned after the etching and preparation of the electrically conductive layer 400 and the isolation structure 500 are completed, so that during the etching and preparation of the electrically conductive layer 400 and the isolation structure 500, the pixel definition material layer 10a can better cover the surface of the second electrode 210, and thus the etching material is less likely to cause etching damage to the second electrode 210, thereby better improving the structural stability of the second electrode 210.

Step S26: preparing a first electrode layer 700 including a first electrode 710 at least partially arranged in the isolation opening 500a, in which the first electrode 710 overlaps and connects the isolation structure 500 as shown in FIG. 44.

Optionally, one of the first electrode 710 and the second electrode 210 may be used as an anode and the other may be used as a cathode, so as to drive the light-emitting unit 610 to emit light. In the embodiments of the present application, for example, the first electrode 710 is the cathode of the display panel 10, and the second electrode 210 is the anode of the display panel 10.

Optionally, step S26 may further include: preparing a light-emitting layer 600, in which the light-emitting layer 600 includes a light-emitting unit 610 located at a side of the first electrode 710 facing the base plate 100.

In the manufacturing method according to the embodiments of the present application, the first electrode 710 overlaps and connects the isolation structure 500, so that adjacent first electrodes 710 can be electrically connected with each other through the isolation structure 500 to form a surface electrode, so as to facilitate the control of the first electrode 710 in the display panel 10. By providing the light transmission opening 500b on the isolation structure 500, the display panel 10 can have a better light transmission capability. By exposing at least a part of the electrically conductive layer 400 in the light transmission opening 500b, the electrically conductive layer 400 can better reduce the crosstalk generated between the signals in the base plate 100 and the signals in a device arranged at a side of the electrically conductive layer 400 away from the base plate 100 through the light transmission opening 500b. For example, the electrically conductive layer 400 can better reduce the crosstalk generated between the signals in the base plate 100 and the touch control signals in the touch control electrode 910 located at a side of the shielding portion 420 away from the base plate 100 through the light transmission opening 500b so that not only the display panel 10 can have a better light transmission capability, but also the display panel 10 can have a better working stability.

In some optional embodiments of the present application, the surface at locations where etching is not required may be coated with a photoresist material for protection when a wet etch or dry etch process is used. Optionally, the coating of the photoresist may be performed using a common mask. For example, the coating of the photoresist may be performed before step S24, and then the coating of the photoresist may be performed once after the removal of the original photoresist material before step S25. Optionally, the coating of the photoresist may be performed using similar devices such as a halftone mask to form a photoresist with varying thickness.

Optionally, the manufacturing method, before step S24, may include: forming a photoresist layer 15 on the isolation material layer 10c, in which the photoresist layer 15 includes a first thickness area 15a, a second thickness area 15b, and a first hollow area 15c, a part of the isolation material layer 10c is exposed in the first hollow area 15c, and a thickness of the photoresist layer 15 located in the first thickness area 15a is greater than a thickness of the photoresist layer 15 located in the second thickness area 15b as shown in FIG. 45.

Optionally, the forming a photoresist layer 15 on the isolation material layer 10c may include: forming the photoresist layer 15 on the isolation material layer 10c using a halftone mask.

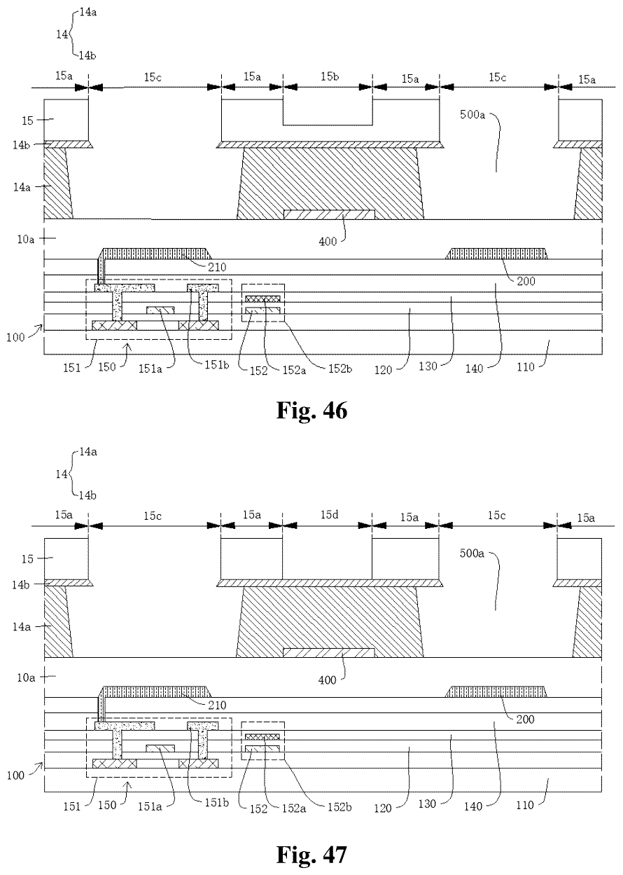

Step S24 may further include: patterning the isolation material layer 10c corresponding to the first hollow area 15c to form the fourth preliminary structure 14 as shown in FIG. 46.

The manufacturing method, after step S24, may further include: removing the photoresist layer 15 in the second thickness area 15b using an ashing process to form a second hollow area 15d as shown in FIG. 47.

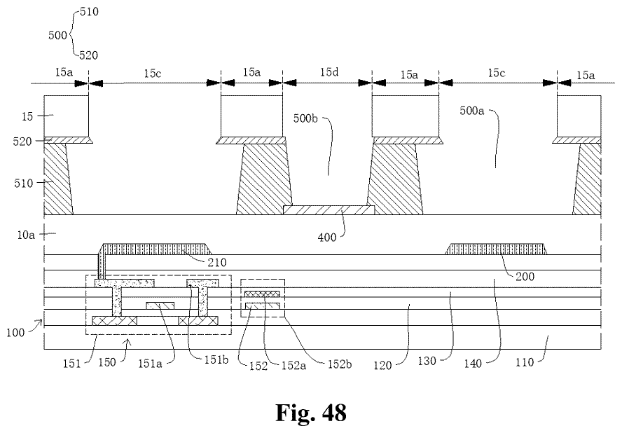

Step S25 may further include: patterning the fourth preliminary structure 14 corresponding to the second hollow area 15d to form the isolation structure 500 as shown in FIG. 48.

In this optional embodiment, the photoresist layer 15 is formed using the halftone mask before patterning the isolation material layer 10c so that the photoresist layer 15 can have the first thickness area 15a, the second thickness area 15b, and the first hollow area 15c that have different thicknesses. In step S24, the etching material may etch the material exposed in the first hollow area 15c. For example, the isolation material layer 10c exposed in the first hollow area 15c may be etched using a dry etching process firstly so as to obtain the isolation preliminary opening 10f, and then the inner wall enclosing and forming the isolation preliminary opening 10f and being exposed in the first hollow area 15c may be etched using a wet etching method so as to obtain the isolation opening 500a. After step S24, the photoresist layer 15 in the second thickness area 15b is removed by using an ashing process to form the second hollow area 15d, so that a part of the fourth preliminary structure 14 can be exposed in the second hollow area 15d, so as to facilitate the process of patterning the part of the fourth preliminary structure 14 exposed in the second hollow area 15d to form the light transmission opening 500b in step S25. In the above steps, the times of coating the photoresist material can be reduced when the coating of the photoresist material is performed using the halftone mask compared to the common mask, and the manufacturing efficiency of the display panel 10 can be improved.

The above embodiments of the present application do not exhaustively describe all the details, nor do they limit the present application to the specific embodiments as described. Obviously, according to the above description, many modifications and changes can be made. These embodiments are selected and particularly described in the specification to better explain the principles and practical applications of the present application, so that a person skilled in the art is able to utilize the present application and make modifications based on the present application. The present application is limited only by the claims and the full scope and equivalents of the claims.

What is claimed is:

1. A display panel, comprising:
a base plate;
an electrically conductive layer arranged at a side of the base plate and comprising a connection portion and a shielding portion;
an isolation structure arranged at a side of the electrically conductive layer away from the base plate, wherein the isolation structure encloses and forms an isolation opening and a light transmission opening, and at least a part of the shielding portion is exposed in the light transmission opening;
a first electrode layer comprising a first electrode at least partially arranged in the isolation opening, wherein the first electrode is electrically connected with the connection portion.

2. The display panel according to claim 1, wherein the connection portion is provided with a connection opening, the connection opening is communicated with the isolation opening, and at least a part of the first electrode is arranged in the connection opening.

3. The display panel according to claim 1, wherein a material of the electrically conductive layer comprises a transparent electrically conductive material.

4. The display panel according to claim 1, wherein the connection portion and the shielding portion are in a one-piece structure; and
the isolation structure is arranged at a side of the connection portion away from the base plate.

5. The display panel according to claim 1, wherein the isolation structure comprises a first isolation portion and a second isolation portion located at a side of the first isolation portion away from the base plate, and the second isolation portion protrudes toward the isolation opening from the first isolation portion;
the connection portion extends into the isolation opening;
an orthographic projection of the first isolation portion on the base plate is located within an orthographic projection of the connection portion on the base plate;
an orthographic projection of a surface at a side of the second isolation portion facing the light transmission opening on the base plate is located within an orthographic projection of a surface at a side the first isolation portion away from the base plate on the base plate.

6. The display panel according to claim 1, wherein an orthographic projection of the shielding portion on the base plate at least partially overlaps an orthographic projection of the light transmission opening on the base plate; or
the orthographic projection of the shielding portion on the base plate is located within the orthographic projection of the light transmission opening on the base plate.

7. The display panel according to claim 1, wherein the isolation structure encloses and forms a plurality of light transmission openings, and the plurality of light transmission openings are arranged along a periphery of the isolation opening; and
an orthographic projection of the light transmission opening on the base plate is in a rectangular shape, a square shape, a circular shape, or an irregular polygonal shape.

8. The display panel according to claim 1, wherein an orthographic projection of the light transmission opening on the base plate is in a ring shape, and the light transmission opening is arranged around at least a part of the isolation opening.

9. The display panel according to claim 1, wherein the display panel further comprises a light-emitting layer, and the light-emitting layer comprises a light-emitting unit located at a side of the first electrode facing the base plate;
the display panel further comprises a second electrode layer, and the second electrode layer comprises a second electrode located a side of the light-emitting unit facing the base plate;
the display panel further comprises a pixel definition portion arranged between the second electrode and the connection portion; and
the electrically conductive layer is arranged at a side of the pixel definition portion away from the base plate, or the pixel definition portion is provided with an accommodating slot, and at least a part of the electrically conductive layer and the isolation structure are located in the accommodating slot.

10. The display panel according to claim 1, wherein a cross-section area of the light transmission opening increases in a direction away from the base plate.

11. The display panel according to claim 1, wherein the display panel further comprises a touch control component located at a side of the isolation structure away from the base plate, the touch control component comprises a touch control electrode, and an orthographic projection of the touch control electrode on the base plate is not overlapped with an orthographic projection of the light transmission opening on the base plate;
the orthographic projection of the touch control electrode on the base plate at least partially overlaps an orthographic projection of the isolation structure on the base plate; or
the orthographic projection of the touch control electrode on the base plate is located within the orthographic projection of the isolation structure on the base plate.

12. The display panel according to claim 1, wherein the display panel has a display area and a non-display area, the display area comprises a first area and a second area, the isolation opening is located in the first area and the second area, and the light transmission opening is located in the second area; and
a light transmittance of the second area is greater than a light transmittance of the first area.

13. A display panel having a display area and a non-display area, the display panel comprising:
a base plate;
an electrically conductive layer arranged at a side of the base plate and comprising a connection portion and a shielding portion, wherein at least a part of the shielding portion is located in the non-display area;
an isolation structure located in the display area and arranged at a side of the electrically conductive layer away from the base plate, wherein the isolation structure encloses and forms an isolation opening;
a first electrode layer comprising a first electrode at least partially arranged in the isolation opening, wherein the first electrode is electrically connected with the connection portion.

14. The display panel according to claim 13, wherein the connection portion and the shielding portion are in a one-piece structure;
the isolation structure is arranged at a side of the connection portion away from the base plate;
the isolation structure further encloses and forms a light transmission opening, and a part of the shielding portion is exposed in the light transmission opening;
a material of the electrically conductive layer comprises a transparent electrically conductive material.

15. A display apparatus, comprising the display panel according to claim 1.

16. A manufacturing method for a display panel, comprising:
forming an electrically conductive material layer and an isolation material layer that are stacked on a base plate in sequence;
patterning the electrically conductive material layer and the isolation material layer to form an electrically conductive layer and an isolation structure, wherein the electrically conductive layer comprises a connection portion and a shielding portion that are connected with each other, the isolation structure is arranged at a side of the electrically conductive layer away from the base plate, the isolation structure encloses and forms an isolation opening and a light transmission opening, and at least a part of the shielding portion is exposed in the light transmission opening; and
preparing a first electrode layer comprising a first electrode at least partially arranged in the isolation opening, wherein the first electrode overlaps and connects the connection portion.

17. The manufacturing method according to claim 16, wherein the patterning the electrically conductive material layer and the isolation material layer to form the electrically conductive layer and the isolation structure comprises:
patterning the isolation material layer to form a first preliminary structure, wherein the first preliminary structure is provided with an isolation preliminary opening and a light transmission opening, and at least a part of the electrically conductive material layer is exposed in the isolation preliminary opening and the light transmission opening;
patterning an inner wall enclosing and forming the isolation preliminary opening and the part of the electrically conductive material layer exposed in the isolation preliminary opening to form the isolation structure and the electrically conductive layer; wherein
the isolation structure comprises a first isolation portion and a second isolation portion located at a side of the first isolation portion away from the base plate, and the second isolation portion protrudes toward the isolation opening from the first isolation portion;
the patterning the isolation material layer to form the first preliminary structure comprises:
performing a dry etching treatment on the isolation material layer to form the first preliminary structure; and
the patterning the inner wall of the first preliminary structure enclosing and forming the isolation preliminary opening and the part of the electrically conductive material layer exposed in the isolation preliminary opening comprises:
performing a wet etching treatment on the inner wall of the first preliminary structure enclosing and forming the isolation preliminary opening and the part of the electrically conductive material layer exposed in the isolation preliminary opening.

18. The manufacturing method according to claim 16, wherein the patterning the electrically conductive material layer and the isolation material layer to form the electrically conductive layer and the isolation structure comprises:
patterning the isolation material layer and the electrically conductive material layer to form a second preliminary structure and the electrically conductive layer, wherein the second preliminary structure is provided with the isolation opening, the second preliminary structure comprises a first preliminary isolation portion and a second preliminary isolation portion located at a side of the first preliminary isolation portion away from the base plate, and the second preliminary isolation portion protrudes toward the isolation opening from the first preliminary isolation portion; and
patterning the second preliminary structure to form the isolation structure, wherein the isolation structure comprises a first isolation portion and a second isolation portion located at a side of the first isolation portion away from the base plate, and the second isolation portion protrudes toward the isolation opening from the first isolation portion; wherein
the patterning the isolation material layer and the electrically conductive material layer to form the second preliminary structure and the electrically conductive layer comprises:
performing a dry etching treatment on the isolation material layer to form an isolation preliminary opening; and
performing a wet etching treatment on an inner wall enclosing and forming the isolation preliminary opening and a part of the electrically conductive material layer exposed in the isolation preliminary opening to form a second preliminary structure and the conductive layer;
the patterning the second preliminary structure to form the isolation structure comprises:
performing a dry etching treatment on the second preliminary structure to form the isolation structure;
before patterning the isolation material layer and the electrically conductive material layer to form the second preliminary structure and the electrically conductive layer, the manufacturing method comprises:
forming a photoresist layer on the isolation material layer, wherein the photoresist layer comprises a first thickness area, a second thickness area, and a first hollow area, a part of the isolation material layer is exposed in the first hollow area, and a thickness of the photoresist layer located in the first thickness area is greater than a thickness of the photoresist layer located in the second thickness area;
the patterning the isolation material layer and the electrically conductive material layer to form the second preliminary structure and the electrically conductive layer further comprises:
patterning the isolation material layer and the electrically conductive material layer corresponding to the first hollow area to form the second preliminary structure and the electrically conductive layer;
after patterning the isolation material layer and the electrically conductive material layer to form the second preliminary structure and the electrically conductive layer, the manufacturing method comprises:
removing the photoresist layer in the second thickness area using an ashing process to form a second hollow area;
the patterning the second preliminary structure to form the isolation structure further comprises:
patterning the second preliminary structure corresponding to the second hollow area to form the isolation structure; and
the forming the photoresist layer on the isolation material layer comprises:
forming the photoresist layer on the isolation material layer using a halftone mask.

19. The manufacturing method according to claim 16, wherein before forming the electrically conductive material layer and the isolation material layer that are stacked on the base plate in sequence, the manufacturing method further comprises:
preparing a second electrode layer on the base plate, wherein the second electrode layer comprises a plurality of second electrodes arranged at intervals; and
forming a pixel definition material layer on the second electrode layer;
the forming the electrically conductive material layer and the isolation material layer that are stacked on the base plate in sequence comprises: forming the conductive material layer and the isolating material layer that are stacked on the pixel definition material layer in sequence;
after the patterning the electrically conductive material layer and the isolation material layer to form the electrically conductive layer and the isolation structure, the manufacturing method further comprises:
patterning the pixel definition material layer to form a pixel definition portion arranged between the second electrode and the connection portion;
the display panel has a display area and a non-display area, and a part of the shielding portion is located in the non-display area;
the base plate comprises a power supply voltage signal line, and after forming the pixel definition material layer on the second electrode layer, the manufacturing method comprises:
performing an opening treatment on the pixel definition material layer and the base plate located in the non-display area to form a via hole, wherein at least a part of the power supply voltage signal line is exposed in the via hole; and
forming the conductive material layer and the isolating material layer that are stacked on the pixel definition material layer in sequence, wherein at least a part of the electrically conductive material layer is located in the via hole and is connected with the power supply voltage signal line.
